(19) United States
(12) Patent Application Publication
(10) Pub. No.: US 2026/0282300 A1
(43) Pub. Date: Sep. 17, 2026

(54) Power Conversion Apparatus

(71) Applicant: Mitsubishi Electric Corporation, Chiyoda-ku, Tokyo (JP)

(72) Inventors: Yukiko MORI, Chiyoda-ku, Tokyo (JP); Yuji SHIRAKATA, Chiyoda-ku, Tokyo (JP); Hiroyuki YAHARA, Chiyoda-ku, Tokyo (JP); Kenta FUJII, Chiyoda-ku, Tokyo (JP); Noriya MINAMI, Chiyoda-ku, Tokyo (JP)

(73) Assignee: Mitsubishi Electric Corporation, Chiyoda-ku, Tokyo (JP)

(21) Appl. No.: 19/166,960

(22) PCT Filed: Mar. 7, 2024
(86) PCT No.: PCT/JP2024/008824

§ 371 Date: Sep. 19, 2025

(30) Foreign Application Priority Data
Mar. 27, 2023 (JP) 2023-049630

(51) Int. Cl. H05K 7/20

(52) U.S. Cl. CPC H05K 7/209

(57) ABSTRACT

A power conversion apparatus includes a plurality of circuit components, a metal base substrate, a first heat transport member, and a cooler. The metal base substrate includes: a main surface on which the plurality of circuit components are mounted; and an end surface connected to the main surface. The first heat transport member includes a main surface and an end surface facing the cooler. The end surface and the end surface are thermally connected to the cooler. The main surface is thermally connected to the metal base substrate.

### TECHNICAL FIELD

The present disclosure relates to a power conversion apparatus.

### BACKGROUND ART

Japanese Patent No. 4983959 (PTL 1) discloses a switching power supply including: an electronic component; an accommodation case that accommodates the electronic component; a base portion formed integrally with the accommodation case and on which the electronic component is placed; and a refrigerant flow path passing through the base portion and through which refrigerant for cooling the electronic component flows.

### CITATION LIST

### Patent Literature

PTL 1: Japanese Patent No. 4983959

### SUMMARY OF INVENTION

### Technical Problem

An object of the present disclosure is to provide a power conversion apparatus in which a plurality of circuit components can be cooled without increasing the size of a cooler even when the number of the circuit components increases.

### Solution to Problem

A power conversion apparatus according to a first aspect of the present disclosure includes: a plurality of circuit components; a metal base substrate including a metal plate; a heat transport member; and a cooler. The metal base substrate includes: a first main surface on which the plurality of circuit components are mounted; and a first end surface connected to the first main surface. A thermal conductivity of the heat transport member is equal to or higher than a thermal conductivity of the metal plate. The heat transport member includes: a second main surface; and a second end surface connected to the second main surface and facing the cooler. The first end surface and the second end surface are thermally connected to the cooler. The second main surface is thermally connected to the metal base substrate.

A power conversion apparatus according to a second aspect of the present disclosure includes: a plurality of circuit components; a metal base substrate including a metal plate: a heat transport member; and a cooler. The metal base substrate includes: a first main surface on which the plurality of circuit components are mounted; a second main surface opposite to the first main surface; and a first end surface connected to the first main surface and the second main surface. The metal plate includes the second main surface. The first end surface faces the cooler and is thermally connected to the cooler. A thermal conductivity of the heat transport member is equal to or higher than a thermal conductivity of the metal plate. The heat transport member faces the second main surface and is thermally connected to the second main surface. In a plan view of the first main surface, the heat transport member includes a protrusion protruding from the first end surface. The cooler is provided with a hole or a recess. The protrusion of the heat transport member is inserted into the hole or the recess and thermally connected to the cooler.

### Advantageous Effects of Invention

The cooler is thermally connected to the first end surface of the metal base substrate and the heat transport member. The heat generated in the plurality of circuit components is transferred to the cooler through both the metal base substrate and the heat transport member and then collected in the cooler. According to the power conversion apparatus of the present disclosure, even if the number of the circuit components increases to thereby increase the size of the metal base substrate, the plurality of circuit components can be cooled without increasing the size of the cooler.

### BRIEF DESCRIPTION OF DRAWINGS

FIG. 1 is a circuit diagram of a power conversion apparatus according to a first embodiment.

FIG. 2 is a schematic plan view of the power conversion apparatus according to the first embodiment.

FIG. 3 is a schematic cross-sectional view of the power conversion apparatus according to the first embodiment, taken along a cross-sectional line III-III shown in FIG. 2.

FIG. 4 is a schematic partially enlarged cross-sectional view of a region IV shown in FIG. 3 in the power conversion apparatus according to the first embodiment.

FIG. 5 is a schematic cross-sectional view of a power conversion apparatus according to a second embodiment.

FIG. 6 is a schematic cross-sectional view of a power conversion apparatus according to a third embodiment.

FIG. 7 is a schematic plan view of a power conversion apparatus according to a fourth embodiment.

FIG. 8 is a schematic cross-sectional view of the power conversion apparatus according to the fourth embodiment, taken along a cross-sectional line VIII-VIII shown in FIG. 7.

FIG. 9 is a schematic cross-sectional view of the power conversion apparatus according to the fourth embodiment, taken along a cross-sectional line IX-IX shown in FIG. 7.

FIG. 10 is a schematic plan view of a power conversion apparatus according to a fifth embodiment.

FIG. 11 is a schematic cross-sectional view of the power conversion apparatus according to the fifth embodiment, taken along a cross-sectional line XI-XI shown in FIG. 10.

FIG. 12 is a schematic plan view of a power conversion apparatus according to a sixth embodiment.

FIG. 13 is a schematic cross-sectional view of the power conversion apparatus according to the sixth embodiment, taken along a cross-sectional line XIII-XIII shown in FIG. 12.

FIG. 14 is a schematic cross-sectional view of the power conversion apparatus according to the sixth embodiment, taken along a cross-sectional line XIV-XIV shown in FIG. 12.

FIG. 15 is a schematic cross-sectional view of the power conversion apparatus according to the sixth embodiment, taken along a cross-sectional line XV-XV shown in FIG. 12.

FIG. 16 is a schematic plan view of a power conversion apparatus according to a seventh embodiment.

FIG. 17 is a schematic cross-sectional view of the power conversion apparatus according to the seventh embodiment, taken along a cross-sectional line XVII-XVII shown in FIG. 16.

FIG. 18 is a schematic cross-sectional view of the power conversion apparatus according to the seventh embodiment, taken along a cross-sectional line XVIII-XVIII shown in FIG. 16.

FIG. 19 is a schematic cross-sectional view of the power conversion apparatus according to the seventh embodiment, taken along a cross-sectional line XIX-XIX shown in FIG. 16.

FIG. 20 is a schematic plan view of a power conversion apparatus according to an eighth embodiment.

FIG. 21 is a schematic cross-sectional view of the power conversion apparatus according to the eighth embodiment, taken along a cross-sectional line XXI-XXI shown in FIG. 20.

FIG. 22 is a schematic cross-sectional view of the power conversion apparatus according to the eighth embodiment, taken along a cross-sectional line XXII-XXII shown in FIG. 20.

FIG. 23 is a schematic cross-sectional view of the power conversion apparatus according to the eighth embodiment, taken along a cross-sectional line XXIII-XXIII shown in FIG. 20.

FIG. 24 is a schematic cross-sectional view of a power conversion apparatus according to a ninth embodiment.

FIG. 25 is a schematic cross-sectional view of a power conversion apparatus according to a tenth embodiment.

FIG. 26 is a schematic cross-sectional view of a power conversion apparatus according to another modification of the tenth embodiment.

FIG. 27 is a schematic cross-sectional view of a power conversion apparatus according to an eleventh embodiment.

FIG. 28 is a schematic cross-sectional view of a power conversion apparatus according to a modification of the eleventh embodiment.

FIG. 29 is a schematic cross-sectional view of a power conversion apparatus according to a twelfth embodiment.

FIG. 30 is a schematic cross-sectional view of a power conversion apparatus according to a modification of the twelfth embodiment.

FIG. 31 is a schematic plan view of a power conversion apparatus according to a thirteenth embodiment.

FIG. 32 is a schematic cross-sectional view of the power conversion apparatus according to the thirteenth embodiment, taken along a cross-sectional line XXXII-XXXII shown in FIG. 31.

FIG. 33 is a schematic diagram of the power conversion apparatus according to the thirteenth embodiment as viewed in a direction of an arrow XXXIII shown in FIG. 31.

FIG. 34 is a schematic plan view of a power conversion apparatus according to a first modification of the thirteenth embodiment.

FIG. 35 is a schematic cross-sectional view of the power conversion apparatus according to the first modification of the thirteenth embodiment, taken along a cross-sectional line XXXV-XXXV shown in FIG. 34.

FIG. 36 is a schematic diagram of the power conversion apparatus according to the first modification of the thirteenth embodiment, as viewed in a direction of an arrow XXXVI shown in FIG. 34.

FIG. 37 is a schematic plan view of a power conversion apparatus according to a second modification of the thirteenth embodiment.

FIG. 38 is a schematic cross-sectional view of the power conversion apparatus according to the second modification of the thirteenth embodiment, taken along a cross-sectional line XXXVIII-XXXVIII shown in FIG. 37.

FIG. 39 is a schematic diagram of the power conversion apparatus according to the second modification of the thirteenth embodiment, as viewed in a direction of an arrow XXXIX shown in FIG. 37.

FIG. 40 is a schematic plan view of a power conversion apparatus according to a third modification of the thirteenth embodiment.

FIG. 41 is a schematic cross-sectional view of the power conversion apparatus according to the third modification of the thirteenth embodiment, taken along a cross-sectional line XLI-XLI shown in FIG. 40.

FIG. 42 is a schematic diagram of the power conversion apparatus according to the third modification of the thirteenth embodiment, as viewed in a direction of an arrow XLII shown in FIG. 40.

FIG. 43 is a schematic plan view of a power conversion apparatus according to a fourth modification of the thirteenth embodiment.

FIG. 44 is a schematic cross-sectional view of the power conversion apparatus according to the fourth modification of the thirteenth embodiment, taken along a cross-sectional line XLIV-XLIV shown in FIG. 43.

FIG. 45 is a schematic diagram of the power conversion apparatus according to the fourth modification of the thirteenth embodiment, as viewed in a direction of an arrow XLV shown in FIG. 43.

FIG. 46 is a schematic plan view of a power conversion apparatus according to a fifth modification of the thirteenth embodiment.

FIG. 47 is a schematic cross-sectional view of the power conversion apparatus according to the fifth modification of the thirteenth embodiment, taken along a cross-sectional line XL VII-XL VII shown in FIG. 46.

FIG. 48 is a schematic diagram of the power conversion apparatus according to the fifth modification of the thirteenth embodiment, as viewed in a direction of an arrow XLVIII shown in FIG. 46.

### DESCRIPTION OF EMBODIMENTS

Hereinafter, embodiments of the present disclosure will be described. It should be noted that the same configurations are denoted by the same reference characters, and the description thereof will not be repeated.

### First Embodiment.

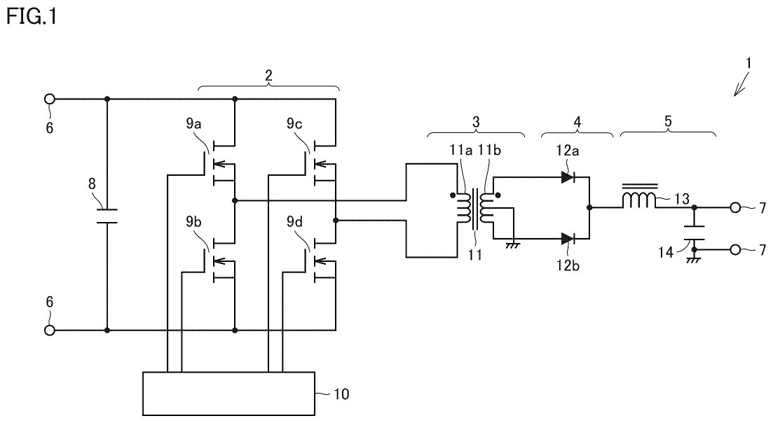

Referring to FIG. 1, an example of a circuit configuration of a power conversion apparatus 1 according to the first embodiment will be described. Power conversion apparatus 1 includes an inverter circuit 2, a transformer circuit 3, a rectifier circuit 4, a smoothing circuit 5, an input terminal 6, an output terminal 7, an input capacitor 8, and a control circuit 10. Power conversion apparatus 1 is, for example, a direct-current (DC)/DC converter mounted in an electric vehicle. For example, an input DC voltage of 100 V to about 300 V from a lithium ion battery is input to input terminal 6. Power conversion apparatus 1 converts the input DC voltage, for example, into an output DC voltage of 12 V to 15 V. The output DC voltage is output from output terminal 7. The output DC voltage is used, for example, to charge a lead-acid battery.

Input capacitor 8 is connected to input terminal 6 and inverter circuit 2. Input capacitor 8 reduces the ripple voltage.

Inverter circuit 2 converts the input DC voltage input from input terminal 6 into a first AC voltage. Inverter circuit 2 includes switching elements 9a, 9b, 9c, and 9d. Switching elements 9a, 9b, 9c, and 9d are, for example, power semiconductor elements such as metal oxide semiconductor field-effect transistors (MOSFETs) or insulated gate bipolar transistors (IGBTs). Switching elements 9a, 9b, 9c, and 9d each are formed of a semiconductor material such as silicon (Si), silicon carbide (SIC), or gallium nitride (GaN).

Control circuit 10 controls switching elements 9a, 9b, 9c, and 9d included in inverter circuit 2.

Transformer circuit 3 converts the first AC voltage output from inverter circuit 2 into a second AC voltage. Transformer circuit 3 includes a transformer 11. Transformer 11 includes a primary winding 11a and a secondary winding 11b. Primary winding 11a is connected to inverter circuit 2. Secondary winding 11b is connected to rectifier circuit 4. Secondary winding 11b is magnetically coupled to primary winding 11a. The ratio between the first AC voltage and the second AC voltage depends on the winding ratio between primary winding 11a and secondary winding 11b. Transformer 11 provides electrical insulation between input terminal 6 and output terminal 7.

Rectifier circuit 4 converts the second AC voltage output from transformer circuit 3 into an output DC voltage. Rectifier circuit 4 includes rectifier elements 12a and 12b. Rectifier elements 12a and 12b are, for example, power semiconductor elements such as diodes, MOS transistors, or thyristors. Rectifier elements 12a and 12b each are formed of a semiconductor material such as Si, SIC, or GaN.

Smoothing circuit 5 is connected to rectifier circuit 4 and output terminal 7. Smoothing circuit 5 includes a smoothing reactor 13 and a smoothing capacitor 14. In smoothing circuit 5, the output DC voltage converted by rectifier circuit 4 is smoothed by smoothing reactor 13 and smoothing capacitor 14. Thus, the output DC voltage output from output terminal 7 is stabilized.

In power conversion apparatus 1, switching elements 9a, 9b, 9c, and 9d, rectifier elements 12a and 12b, transformer 11, and smoothing reactor 13 are electronic components that each generate a large amount of heat. Failures are more likely to occur in transformer 11 and smoothing reactor 13 due to the influence of the heat from these electronic components that each generate a large amount of heat. Thus, power conversion apparatus 1 needs to be cooled.

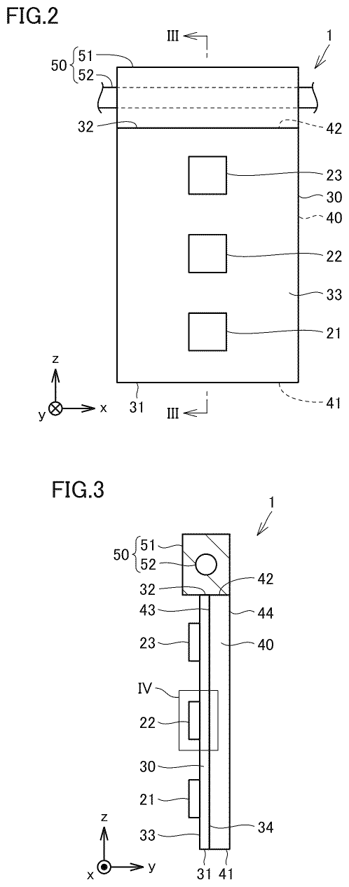

Referring to FIGS. 2 to 4. the configuration of power conversion apparatus 1 according to the present embodiment will be described. Power conversion apparatus 1 includes a metal base substrate 30, a plurality of circuit components 21, 22, and 23, a cooler 50, and a first heat transport member 40.

Metal base substrate 30 includes an end surface 31, an end surface 32 opposite to end surface 31, a main surface 33, and a main surface 34 opposite to main surface 33. End surfaces 31 and 32 are, for example, both end surfaces of metal base substrate 30 in its long-side direction (for example, a z direction). The long-side direction (for example, the z direction) of metal base substrate 30 is not particularly limited, but may be the direction of gravity. End surface 31 is a distal end surface of metal base substrate 30 with respect to cooler 50. End surface 32 is a proximal end surface of metal base substrate 30 with respect to cooler 50. End surface 32 faces cooler 50.

Each of main surfaces 33 and 34 extends in the long-side direction (for example, the z direction) of metal base substrate 30 and in a short-side direction (for example, an x direction) of metal base substrate 30 perpendicular to the long-side direction (for example, the z direction) of metal base substrate 30. Main surfaces 33 and 34 each are connected to end surfaces 31 and 32. Main surfaces 33 and 34 are both end surfaces of metal base substrate 30 in its thickness direction (for example, a y direction).

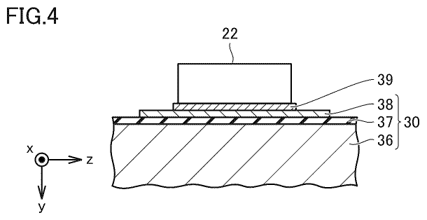

Referring to FIG. 4, metal base substrate 30 includes a metal plate 36, an insulating layer 37, and a circuit pattern 38.

Metal plate 36 is, for example, made of a metal material such as copper, iron, aluminum, a copper alloy, or an aluminum alloy. Metal plate 36 has a thermal conductivity, for example, of 1.0 W/(m·K) or more. Metal plate 36 may have a thermal conductivity of 10.0 W/(m·K) or more, or may have a thermal conductivity of 100.0 W/(m·K) or more. Metal plate 36 supports the plurality of circuit components 21, 22, and 23, and transfers the heat generated in the plurality of circuit components 21, 22, and 23 to cooler 50. Metal plate 36 is, for example, a rigid substrate.

Insulating layer 37 has electrical insulation properties and is provided on metal plate 36. Insulating layer 37 electrically insulates circuit pattern 38 from metal plate 36. Insulating layer 37 is made, for example, of an insulating resin such as an epoxy resin, a glass fiber-reinforced epoxy resin, or a polyimide resin. In order to improve the thermal conductivity of insulating layer 37, insulating layer 37 may be made of an insulating resin to which a thermally conductive filler such as a silica filler, an alumina filler, or an aluminum nitride filler is added.

The heat generated in the plurality of circuit components 21, 22, and 23 is transferred to metal plate 36 and first heat transport member 40 through insulating layer 37. Thus, insulating layer 37 is preferably as thin as possible unless the electrical insulating capacity of insulating layer 37 is adversely affected. The thickness of insulating layer 37 is, for example, 1 μm or more and 2000 μm or less. The thickness of insulating layer 37 may be 1 μm or more and 200 μm or less.

Circuit pattern 38 is provided on insulating layer 37. Circuit pattern 38 is made, for example, of a conductive material like metal such as copper, nickel, gold, aluminum, silver, or tin, or an alloy containing these metals. The thickness of circuit pattern 38 is, for example, 1 μm or more and 2000 μm or less.

Referring to FIGS. 2 to 4, main surface 33 of metal base substrate 30 is mainly formed of insulating layer 37 and circuit pattern 38. Main surface 34 of metal base substrate 30 is formed of metal plate 36.

Each of the plurality of circuit components 21, 22, and 23 includes at least one of input capacitor 8, switching elements 93, 9b, 9c, and 9d, transformer 11, rectifier elements 12a and 12b, smoothing reactor 13, or smoothing capacitor 14, each of which is shown in FIG. 1. The plurality of circuit components 21, 22, and 23 may further include other electronic components such as a resistor. The plurality of circuit components 21, 22, and 23 each may include an interconnection component (not shown) such as a lead. The heat generated in the plurality of circuit components 21, 22, and 23 includes heat generated in the interconnection component.

The plurality of circuit components 21, 22, and 23 are mounted on main surface 33 of metal base substrate 30. Circuit components 21, 22, and 23 are electrically connected to circuit pattern 38. Specifically, circuit components 21, 22, and 23 may be fixed to circuit pattern 38 through a conductive bonding member 39 such as solder. Circuit components 21, 22, and 23 may be fixed to circuit pattern 38 by welding or caulking the respective interconnection components (not shown) of circuit components 21, 22, and 23 to circuit pattern 38.

In a plan view of main surface 33, circuit components 21, 22, and 23 are arranged, for example, in a direction (for example, a −z direction) away from cooler 50. Circuit components 21, 22, and 23 are arranged, for example, in a direction (for example, the z direction) perpendicular to end surface 32 of metal base substrate 30 that faces cooler 50. Circuit components 21, 22, and 23 are arranged, for example, in a direction (for example, the z direction) perpendicular to end surface 42 of first heat transport member 40 that faces cooler 50. Among the plurality of circuit components 21, 22, and 23, circuit component 21 is located farthest from cooler 50. Among the plurality of circuit components 21, 22, and 23, circuit component 23 is located closest to cooler 50. Circuit component 22 is located between circuit components 21 and 23.

Referring to FIGS. 2 and 3, cooler 50 cools power conversion apparatus 1 by releasing the beat generated in the plurality of circuit components 21, 22, and 23 to the outside of power conversion apparatus 1. Cooler 50 includes a heat sink 51. Heat sink 51 is, for example, made of metal such as copper, iron, aluminum, an iron alloy, or an aluminum alloy. Heat sink 51 has a thermal conductivity, for example, of 1.0 W/(m·K) or more. Heat sink 51 may have a thermal conductivity of 10.0 W/(m·K) or more, or may have a thermal conductivity of 100.0 W/(m·K) or more. Heat sink 51 dissipates the heat generated in the plurality of circuit components 21, 22, and 23 to the air around heat sink 51.

Cooler 50 may be provided with a flow path for refrigerant. Cooler 50 may further include a cooling pipe 52 passing through heat sink 51 as a flow path for refrigerant. Refrigerant such as air or water flows through cooling pipe 52. The refrigerant carries the heat generated in the plurality of circuit components 21, 22, and 23 to the outside of power conversion apparatus 1. For example, cooling pipe 52 is connected to a refrigerant circulation device (not shown) via a hose (not shown). The hose is, for example, a bendable hose made of resin. When the refrigerant is water, the refrigerant circulation device is, for example, a cooling water circulation device. The refrigerant circulation device supplies refrigerant having a constant temperature to cooling pipe 52 at a constant flow rate.

Cooler 50 is thermally connected to end surface 32 of metal base substrate 30. In the present specification, the state in which a member A is thermally connected to a member B means a state in which member A is in direct contact with member B, or a state in which member A is connected to member B with a heat conductive member having a thermal conductivity of 0.5 W/(m·K) or more being interposed therebetween. Examples of such a thermally conductive member include thermally conductive grease, a thermally conductive sheet, a thermally conductive adhesive, or the like. Cooler 50 is fixed to end surface 32 of metal base substrate 30 by caulking, pressure welding. soldering, brazing, bonding, welding, or the like.

First heat transport member 40 transfers or diffuses the heat generated in the plurality of circuit components 21, 22, and 23 to cooler 50.

First heat transport member 40 includes an end surface 41, an end surface 42 opposite to end surface 41, a main surface 43, and a main surface 44 opposite to main surface 43. End surfaces 41 and 42 are, for example, both end surfaces of first heat transport member 40 in its long-side direction (for example, the z direction). The long-side direction (for example, the z direction) of first heat transport member 40 is not particularly limited, but may be the direction of gravity. End surface 41 is a distal end surface of first heat transport member 40 with respect to cooler 50. End surface 42 is a proximal end surface of first heat transport member 40 with respect to cooler 50. End surface 42 faces cooler 50. Main surfaces 43 and 44 each are connected to end surfaces 41 and 42. Main surfaces 43 and 44 are both end surfaces of first heat transport member 40 in its thickness direction (for example, the y direction).

Main surface 43 of first heat transport member 40 is thermally connected to main surface 34 of metal base substrate 30. Main surface 43 of first heat transport member 40 is fixed to main surface 34 of metal base substrate 30 by caulking, pressure welding, soldering, brazing, bonding, welding, or the like. End surface 42 of first heat transport member 40 is thermally connected to cooler 50. End surface 42 of first heat transport member 40 is fixed to cooler 50 by caulking, pressure welding, soldering, brazing, bonding, welding, or the like.

In the plan view of main surface 33, first heat transport member 40 extends from end surface 32 of metal base substrate 30 to end surface 31 of metal base substrate 30. End surface 41 of first heat transport member 40 may be flush with end surface 31 of metal base substrate 30. End surface 42 of first heat transport member 40 may be flush with end surface 32 of metal base substrate 30. In the plan view of main surface 33, first heat transport member 40 overlaps the plurality of circuit components 21, 22, and 23. In the plan view of main surface 33, first heat transport member 40 may overlap the entire metal base substrate 30.

First heat transport member 40 may be larger in cross-sectional area than metal base substrate 30. First heat transport member 40 may be larger in cross-sectional area than metal plate 36. The cross-sectional area of first heat transport member 40 is an area of the cross section of first heat transport member 40 that is taken along a plane perpendicular to the direction (for example, the z direction) in which the heat generated in the plurality of circuit components 21, 22, and 23 is mainly transferred. The cross-sectional area of metal base substrate 30 is an area of the cross section of metal base substrate 30 that is taken along a plane perpendicular to the direction (for example, the z direction) in which the heat generated in the plurality of circuit components 21, 22, and 23 is mainly transferred. The cross-sectional area of metal plate 36 is an area of the cross section of metal plate 36 that is taken along a plane perpendicular to the direction (for example, the z direction) in which the heat generated in the plurality of circuit components 21, 22, and 23 is mainly transferred.

The thermal conductivity of first heat transport member 40 is equal to or higher than the thermal conductivity of metal plate 36. First heat transport member 40 is, for example, a heat pipe, a vapor chamber, or a graphite sheet, or a metal plate integrated with any of these components. First heat transport member 40 is made, for example, of a metal material such as copper, iron, aluminum, an iron alloy, or an aluminum alloy, or carbon. First heat transport member 40 has a thermal conductivity, for example, of 1.0 W/(m·K) or more. First heat transport member 40 may have a thermal conductivity of 10.0 W/(m·K) or more, or may have a thermal conductivity of 100.0 W/(m·K) or more.

In order to enhance the heat transport capacity, a capillary structure is formed on an inner wall of a heat pipe. Thus, when the heat pipe is bent, the capillary structure is broken, so that the heat transport capacity of the heat pipe decreases. However, in the present embodiment, in the case where first heat transport member 40 is a heat pipe, the heat pipe may be used without being bent. This can prevent a decrease in heat transport capacity of the heat pipe. Further, in the case where first heat transport member 40 is a heat pipe and the long-side direction of first heat transport member 40 corresponds to the direction of gravity, the heat pipe is improved in performance, and cooler 50 can be reduced in size.

The functions of power conversion apparatus 1 according to the present embodiment will be described.

The heat generated in the plurality of circuit components 21, 22, and 23 is transferred to cooler 50 through both metal base substrate 30 and first heat transport member 40. Thus, the thermal resistance of the heat transfer path from each of the plurality of circuit components 21, 22, and 23 to cooler 50 is reduced. The plurality of circuit components 21, 22, and 23 are efficiently cooled by cooler 50. Cooler 50 can be reduced in size.

In a comparative example in which cooler 50 is thermally connected to main surface 34 of metal base substrate 30, as the number of circuit components 21, 22, and 23 increases to thereby increase the size of metal base substrate 30, the size of cooler 50 also increases. On the other hand, in the present embodiment, cooler 50 is thermally connected not to main surface 34 of metal base substrate 30 but to end surface 32 of metal base substrate 30 and end surface 42 of first heat transport member 40. Thus, the heat generated in the plurality of circuit components 21, 22, and 23 is collected in cooler 50 by metal base substrate 30 and first heat transport member 40. Even if the number of circuit components 21, 22, and 23 increases to thereby increase the size of metal base substrate 30, the size of cooler 50 does not need to be increased.

Power conversion apparatus 1 includes first heat transport member 40 in addition to metal base substrate 30. Thus, the difference decreases between: the thermal resistance of the heat transfer path extending to cooler 50 from the circuit component (for example, circuit component 21) disposed farther from cooler 50 among the plurality of circuit components 21, 22, and 23; and the thermal resistance of the heat transfer path extending to cooler 50 from the circuit component (for example, circuit component 23) disposed closer to cooler 50 among the plurality of circuit components 21, 22, and 23. Power conversion apparatus 1 can more uniformly cool the plurality of circuit components 21, 22, and 23. As a circuit component (for example, circuit component 21) disposed farther from cooler 50 among the plurality of circuit components 21, 22, and 23, a circuit component that generates a larger amount of heat can be adopted. The degree of freedom of arrangement of circuit components 21, 22, and 23 is improved. The thermal design of power conversion apparatus 1 is facilitated.

In the plan view of main surface 33, circuit components 21, 22, and 23 are arranged in the direction (for example, the z direction) perpendicular to end surface 32 of metal base substrate 30 that faces cooler 50. Thus, in the plan view of main surface 33, metal base substrate 30 decreases in size in the direction (for example, the x direction) along end surface 32 of metal base substrate 30. In the plan view of main surface 33, cooler 50 decreases in size in the direction (for example, the x direction) along end surface 32 of metal base substrate 30.

The effects of power conversion apparatus 1 of the present embodiment will be described.

Power conversion apparatus 1 includes the plurality of circuit components 21, 22, and 23, metal base substrate 30 including metal plate 36, first heat transport member 40, and cooler 50. Metal base substrate 30 includes: a first main surface (main surface 33) on which the plurality of circuit components 21, 22, and 23 are mounted; and a first end surface (end surface 32) connected to the first main surface. The thermal conductivity of first heat transport member 40 is equal to or higher than the thermal conductivity of metal plate 36. First heat transport member 40 includes: a second main surface (main surface 43); and a second end surface (end surface 42) connected to the second main surface and facing cooler 50. The first end surface and the second end surface are thermally connected to cooler 50. The second main surface is thermally connected to metal base substrate 30.

Thus, the heat generated in the plurality of circuit components 21, 22, and 23 is transferred to cooler 50 through both metal base substrate 30 and first heat transport member 40. Further, cooler 50 is thermally connected to the first end surface (end surface 32) of metal base substrate 30 and the second end surface (end surface 42) of first heat transport member 40. The heat generated in the plurality of circuit components 21, 22, and 23 is collected in cooler 50 by metal base substrate 30 and first heat transport member 40. Even if the number of the plurality of circuit components 21, 22, and 23 increases to thereby increase the size of metal base substrate 30, the plurality of circuit components 21, 22, and 23 can be cooled without increasing the size of cooler 50.

In power conversion apparatus 1, metal base substrate 30 includes a third end surface (end surface 31) opposite to the first end surface (end surface 32). In the plan view of the first main surface (main surface 33), first heat transport member 40 extends from the first end surface to the third end surface.

Thus, the heat generated in the circuit component (for example, circuit component 21) disposed farther from cooler 50 can be transferred to cooler 50 with a lower thermal resistance. The degree of freedom of arrangement of the plurality of circuit components 21, 22, and 23 is improved. The thermal design of power conversion apparatus 1 is facilitated. Cooler 50 can be reduced in size.

### Second Embodiment

Referring to FIG. 5, a power conversion apparatus 1b according to the second embodiment will be described. Power conversion apparatus 1b of the present embodiment has the same configuration as that of power conversion apparatus 1 of the first embodiment, except mainly for the following points.

First heat transport member 40 warps relative to metal base substrate 30. An air layer 55 is present between metal base substrate 30 and first heat transport member 40. The gap between metal base substrate 30 and first heat transport member 40 decreases with an increase in distance from cooler 50 (i.e., as closer to end surface 41 from end surface 42). The gap between end surfaces 32 and 42 is larger than the gap between end surfaces 31 and 41. The gap between end surfaces 32 and 42 is, for example, 10 μm or less. The gap between end surfaces 31 and 41 is, for example, 0 μm.

As shown in FIG. 2. in a plan view of main surface 33, in the arrangement direction (for example, the z direction) of the plurality of circuit components 21, 22, and 23, the lengths of the heat transfer paths from the circuit components to cooler 50 increase with an increase in distance from cooler 50. On the other hand, the thickness of air layer 55 decreases with an increase in distance from cooler 50. Part of the heat generated in the circuit component arranged farther from cooler 50 among circuit components 21, 22, and 23 is transferred to cooler 50 through first heat transport member 40 and thinner air layer 55. Air layer 55 is higher in thermal conductivity than metal base substrate 30 and first heat transport member 40. Thus, the difference decreases between: the thermal resistance of the heat transfer path extending to cooler 50 from the circuit component (for example, circuit component 21) disposed farther from cooler 50; and the thermal resistance of the heat transfer path extending to cooler 50 from the circuit component (for example, circuit component 23) disposed closer to cooler 50.

In addition to the effects of power conversion apparatus 1 of the first embodiment, the following effects of power conversion apparatus 1b of the present embodiment will be described.

In power conversion apparatus 1b, the gap between metal base substrate 30 and first heat transport member 40 decreases with an increase in distance from cooler 50.

Thus, the difference decreases between: the thermal resistance of the heat transfer path extending to cooler 50 from the circuit component (for example, circuit component 21) disposed farther from cooler 50; and the thermal resistance of the heat transfer path extending to cooler 50 from the circuit component (for example, circuit component 23) disposed closer to cooler 50. Power conversion apparatus 1b can more uniformly cool the plurality of circuit components 21, 22, and 23. As a circuit component (for example, circuit component 21) disposed farther from cooler 50 among the plurality of circuit components 21, 22, and 23, a circuit component that generates a larger amount of heat can be adopted. The degree of freedom of arrangement of the plurality of circuit components 21, 22, and 23 is improved. The thermal design of power conversion apparatus 1b is facilitated.

### Third Embodiment

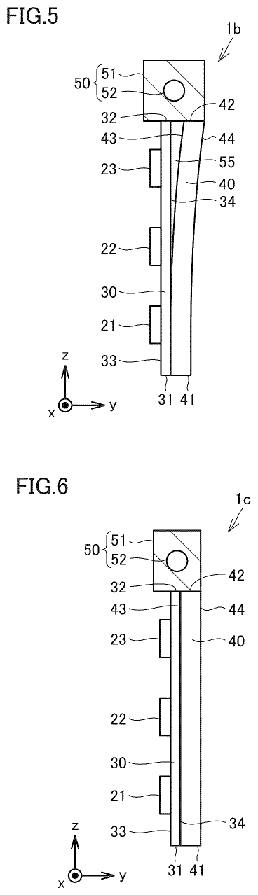

Referring to FIG. 6, a power conversion apparatus 1c according to the third embodiment will be described. Power conversion apparatus 1c of the present embodiment has the same configuration as that of power conversion apparatus 1 of the first embodiment, except mainly for the following points.

In power conversion apparatus 1c, a contact area between metal base substrate 30 and first heat transport member 40 increases with an increase in distance from cooler 50 (i.e., as closer to end surface 41 from end surface 42). For example, the surface roughness of main surface 34 of first heat transport member 40 decreases with an increase in distance from cooler 50.

As shown in FIG. 2, in a plan view of main surface 33, in the arrangement direction (for example, the z direction) of the plurality of circuit components 21, 22, and 23, the lengths of the heat transfer paths from the circuit components to cooler 50 increase with an increase in distance from cooler 50. On the other hand, as the contact area between metal base substrate 30 and first heat transport member 40 increases, the thermal resistance between metal base substrate 30 and first heat transport member 40 decreases. Thus, the difference decreases between: the thermal resistance of the heat transfer path extending to cooler 50 from the circuit component (for example, circuit component 21) disposed farther from cooler 50; and the thermal resistance of the heat transfer path extending to cooler 50 from the circuit component (for example, circuit component 23) disposed closer to cooler 50.

In addition to the effects of power conversion apparatus 1 of the first embodiment, the following effects of power conversion apparatus le of the present embodiment will be described.

In power conversion apparatus 1c, the contact area between metal base substrate 30 and first heat transport member 40 increases with an increase in distance from cooler 50.

Thus, the difference decreases between: the thermal resistance of the heat transfer path extending to cooler 50 from the circuit component (for example, circuit component 21) disposed farther from cooler 50; and the thermal resistance of the heat transfer path extending to cooler 50 from the circuit component (for example, circuit component 23) disposed closer to cooler 50. Power conversion apparatus le can more uniformly cool the plurality of circuit components 21, 22, and 23, As a circuit component (for example, circuit component 21) disposed farther from cooler 50 among the plurality of circuit components 21, 22, and 23, a circuit component that generates a larger amount of heat can be adopted. The degree of freedom of arrangement of the plurality of circuit components 21, 22, and 23 is improved. The thermal design of power conversion apparatus 1c is facilitated.

### Fourth Embodiment

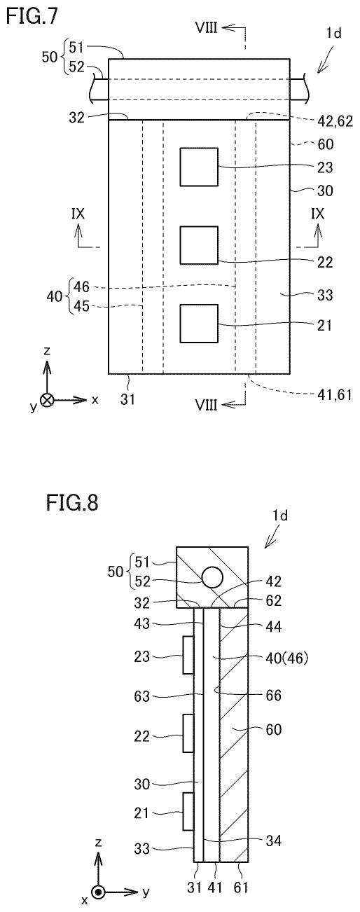

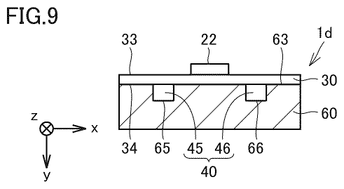

Referring to FIGS. 7 to 9, a power conversion apparatus 1d according to the fourth embodiment will be described. Power conversion apparatus 1d of the present embodiment has the same configuration as that of power conversion apparatus 1 of the first embodiment, except mainly for the following points.

In power conversion apparatus 1d, first heat transport member 40 includes a plurality of heat transport portions 45 and 46,

Heat transport portions 45 and 46 each are thermally connected to main surface 34 of metal base substrate 30. Heat transport portions 45 and 46 each are fixed to main surface 34 of metal base substrate 30 by caulking, pressure welding, soldering. brazing, bonding. welding, or the like. Main surface 43 of first heat transport member 40 is constituted by a main surface of heat transport portion 45 that faces main surface 34 of metal base substrate 30 and a main surface of heat transport portion 46 that faces main surface 34 of metal base substrate 30. Heat transport portions 45 and 46 each are thermally connected to cooler 50. Heat transport portions 45 and 46 each are fixed to cooler 50 by caulking, pressure welding, soldering, brazing, bonding, welding, or the like.

In a plan view of main surface 33, each of heat transport portions 45 and 46 extends from end surface 32 of metal base substrate 30 to end surface 31 of metal base substrate 30. A distal end surface of heat transport portion 45 with respect to cooler 50 and a distal end surface of heat transport portion 46 with respect to cooler 50 may be flush with end surface 31 of metal base substrate 30. A proximal end surface of heat transport portion 45 with respect to cooler 50 and a proximal end surface of heat transport portion 46 with respect to cooler 50 may be flush with end surface 32 of metal base substrate 30. End surface 41 of first heat transport member 40 is constituted by the distal end surface of heat transport portion 45 with respect to cooler 50 and the distal end surface of heat transport portion 46 with respect to cooler 50. End surface 42 of first heat transport member 40 is constituted by the proximal end surface of heat transport portion 45 with respect to cooler 50 and the proximal end surface of heat transport portion 46 with respect to cooler 50.

In power conversion apparatus 1d, first heat transport member 40 does not overlap the plurality of circuit components 21, 22, and 23 in the plan view of main surface 33. Specifically, in the plan view of main surface 33. heat transport portions 45 and 46 do not overlap the plurality of circuit components 21, 22, and 23. In the plan view of main surface 33, the plurality of circuit components 21, 22, and 23 are disposed between heat transport portions 45 and 46. In the plan view of main surface 33, heat transport portions 45 and 46 may be arranged symmetrically with respect to the plurality of circuit components 21, 22, and 23. In the plan view of main surface 33, the gap between heat transport portion 45 and each of the plurality of circuit components 21, 22, and 23 may be equal to the gap between heat transport portion 46 and each of the plurality of circuit components 21, 22, and 23.

Power conversion apparatus 1d further includes a metal support member 60. Metal support member 60 includes an end surface 61, an end surface 62 opposite to end surface 61, and a main surface 63. End surfaces 61 and 62 are, for example, both end surfaces of metal support member 60 in its long-side direction (for example, the z direction). The long-side direction (for example, the z direction) of metal support member 60 is not particularly limited, but may be the direction of gravity. End surface 61 is a distal end surface of metal support member 60 with respect to cooler 50. End surface 62 is a proximal end surface of metal support member 60 with respect to cooler 50. End surface 62 faces cooler 50. Main surface 63 is connected to end surfaces 61 and 62. Main surface 63 is an end surface of metal support member 60 in its thickness direction (for example, the y direction). Main surface 63 faces main surface 44 of first heat transport member 40.

Metal support member 60 supports first heat transport member 40. Specifically, main surface 63 is provided with grooves 65 and 66. Heat transport portion 45 is accommodated in groove 65. Heat transport portion 46 is accommodated in groove 66. Main surface 63 of metal support member 60 may be flush with the main surface of heat transport portion 45 that faces main surface 34 of metal base substrate 30 and the main surface of heat transport portion 46 that faces main surface 34 of metal base substrate 30.

First heat transport member 40 is thermally connected to metal support member 60. First heat transport member 40 is fixed to metal support member 60 by caulking, pressure welding, soldering, brazing, bonding, welding, or the like. Heat transport portions 45 and 46 are thermally connected to metal support member 60. Heat transport portions 45 and 46 are fixed to metal support member 60 by caulking, pressure welding, soldering, brazing, bonding, welding, or the like,

Main surface 63 of metal support member 60 is thermally connected to main surface 34 of metal base substrate 30. Main surface 63 of metal support member 60 is fixed to main surface 34 of metal base substrate 30 by caulking. pressure welding, soldering, brazing, bonding, welding, or the like. End surface 62 of metal support member 60 is thermally connected to cooler 50. End surface 62 of metal support member 60 is fixed to cooler 50 by caulking, pressure welding, soldering, brazing, bonding, welding, or the like.

In the plan view of main surface 33, metal support member 60 overlaps the plurality of circuit components 21, 22, and 23. In the plan view of main surface 33, metal support member 60 may overlap the entire metal base substrate 30 and the entire first heat transport member 40. In the plan view of main surface 33, metal support member 60 extends from end surface 32 of metal base substrate 30 to end surface 31 of metal base substrate 30. In the plan view of main surface 33, metal support member 60 extends from end surface 42 of first heat transport member 40 to end surface 41 of first heat transport member 40.

Metal support member 60 may be larger in cross-sectional area than metal base substrate 30. Metal support member 60 may be larger in cross-sectional area than metal plate 36. Metal support member 60 may be larger in cross-sectional area than first heat transport member 40. The cross-sectional area of metal support member 60 is an area of the cross section of metal support member 60 that is taken along a plane perpendicular to the direction (for example, the z direction) in which the heat generated in the plurality of circuit components 21, 22, and 23 is mainly transferred.

The thermal conductivity of metal support member 60 is equal to or higher than the thermal conductivity of metal plate 36. The thermal conductivity of metal support member 60 is equal to or lower than the thermal conductivity of first heat transport member 40. Metal support member 60 is made, for example, of a metal material such as copper, iron, aluminum, an iron alloy, or an aluminum alloy, Metal support member 60 has a thermal conductivity, for example, of 1.0 W/(m·K) or more. Metal support member 60 may have a thermal conductivity of 10.0 W/(m·K) or more, or may have a thermal conductivity of 100.0 W/(m·K) or more. Metal support member 60 transfers the heat generated in the plurality of circuit components 21, 22, and 23 to cooler 50. Metal support member 60 is, for example, a rigid plate.

In addition to the effects of power conversion apparatus 1 of the first embodiment, the following effects of power conversion apparatus 1d of the present embodiment will be described.

Power conversion apparatus 1d further includes metal support member 60 that supports first heat transport member 40. Metal base substrate 30 includes a third main surface (main surface 34) opposite to the first main surface (main surface 33). The third main surface is connected to the first end surface (end surface 32). Metal support member 60 includes: a fourth main surface (main surface 63) thermally connected to the third main surface; and a fourth end surface (end surface 62) connected to the fourth main surface. The fourth end surface is thermally connected to cooler 50.

Thus, the heat generated in the plurality of circuit components 21. 22, and 23 is transferred to cooler 50 also through metal support member 60 in addition to metal base substrate 30 and first heat transport member 40. The thermal resistance of the heat transfer path from each of the plurality of circuit components 21, 22, and 23 to cooler 50 is reduced. Further, cooler 50 is thermally connected to the first end surface (end surface 32) of metal base substrate 30, the second end surface (end surface 42) of first heat transport member 40, and the fourth end surface (end surface 62) of metal support member 60. The heat generated in the plurality of circuit components 21, 22, and 23 is collected in cooler 50 by metal base substrate 30, first heat transport member 40, and metal support member 60. Even if the number of the plurality of circuit components 21, 22, and 23 increases to thereby increase the size of metal base substrate 30, the plurality of circuit components 21, 22, and 23 can be cooled without increasing the size of cooler 50.

In power conversion apparatus 1d, in addition to the second end surface (end surface 42) of first heat transport member 40, the fourth end surface (end surface 62) of metal support member 60 that supports first heat transport member 40 is also thermally connected to cooler 50. Thus, first heat transport member 40 is easily fixed to cooler 50. Further, when metal support member 60 is a rigid plate, the mechanical strength of power conversion apparatus 1d is enhanced.

### Fifth Embodiment

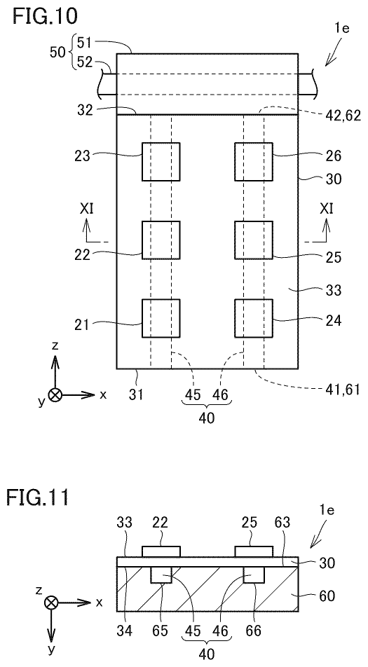

Referring to FIGS. 10 and 11, a power conversion apparatus 1e according to the fifth embodiment will be described. Power conversion apparatus 1e of the present embodiment has the same configuration as that of power conversion apparatus 1d of the fourth embodiment, except mainly for the following points.

Power conversion apparatus le further includes circuit components 24, 25, and 26. In a plan view of main surface 33, circuit components 24, 25, and 26 are arranged, for example, in the direction (the −z direction) away from cooler 50. In the plan view of main surface 33, circuit components 24, 25, and 26 are arranged, for example, in the long-side direction (for example, the z direction) of metal base substrate 30. In the plan view of main surface 33, circuit components 24, 25, and 26 are arranged, for example, in the direction (for example, the z direction) perpendicular to end surface 32 of metal base substrate 30. In the plan view of main surface 33, circuit components 24, 25, and 26 are arranged, for example, in the direction (for example, the z direction) perpendicular to end surface 42 of first heat transport member 40.

Circuit component 24 is disposed farthest from cooler 50 among circuit components 24, 25, and 26. Circuit component 26 is disposed closest to cooler 50 among circuit components 24, 25, and 26. Circuit component 25 is disposed between circuit components 24 and 26. Circuit components 24, 25, and 26 are disposed to be displaced from circuit components 21, 22, and 23 in the short-side direction (for example, the x direction) of metal base substrate 30.

Each of circuit components 24, 25, and 26 includes at least one of input capacitor 8, switching elements 9a, 9b, 9e, and 9d, transformer 11, rectifier elements 12a and 12b, smoothing reactor 13, or smoothing capacitor 14, each of which is shown in FIG. 1. Circuit components 24, 25, and 26 may further include other electronic components such as a resistor. Each of circuit components 24, 25, and 26 may include an interconnection component (not shown) such as a lead. The heat generated in the plurality of circuit components 24, 25, and 26 includes the heat generated in the interconnection component.

In the plan view of main surface 33, first heat transport member 40 overlaps the plurality of circuit components 21, 22, 23, 24, 25, and 26. Specifically, in the plan view of main surface 33, heat transport portion 45 overlaps circuit components 21, 22, and 23. In the plan view of main surface 33, heat transport portion 46 overlaps circuit components 24, 25, and 26.

In addition to the effects of power conversion apparatus 1d of the fourth embodiment, the following effects of power conversion apparatus 1e of the present embodiment will be described.

In power conversion apparatus le, the plurality of circuit components 21, 22, 23, 24, 25, and 26 overlap first heat transport member 40 in the plan view of the first main surface (main surface 33).

Thus, the heat transfer path from each of the plurality of circuit components 21, 22, 23, 24, 25, and 26 to cooler 50 shortens, so that the thermal resistance of the heat transfer path from each of the plurality of circuit components 21, 22, 23, 24, 25, and 26 to cooler 50 is reduced. Even if the number of the plurality of circuit components 21, 22, 23, 24, 25, and 26 increases to thereby increase the size of metal base substrate 30, the plurality of circuit components 21, 22, 23, 24, 25, and 26 can be cooled without increasing the size of cooler 50.

### Sixth Embodiment

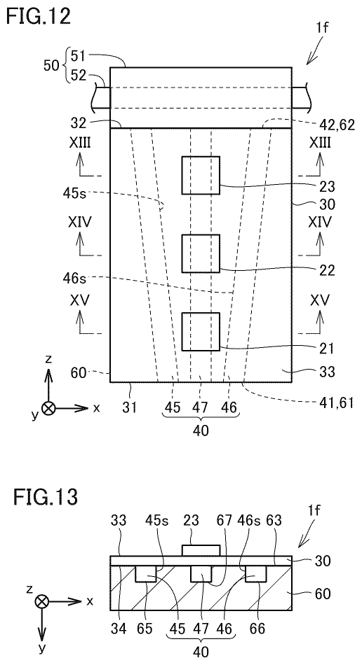

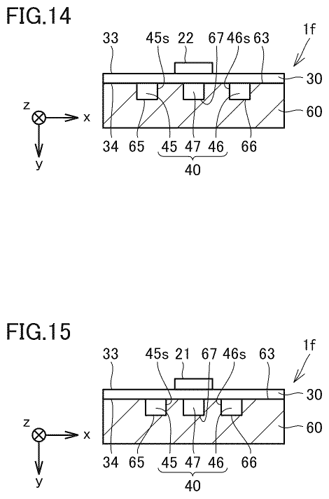

Referring to FIGS. 12 to 15, a power conversion apparatus 1f according to the sixth embodiment will be described. Power conversion apparatus 1f of the present embodiment has the same configuration as that of power conversion apparatus 1d of the fourth embodiment, except mainly for the following points.

First heat transport member 40 includes a heat transport portion 47 in addition to heat transport portions 45 and 46.

Heat transport portion 47 is also thermally connected to main surface 34 of metal base substrate 30. Heat transport portion 47 is fixed to main surface 34 of metal base substrate 30 by caulking, pressure welding, soldering, brazing, bonding, welding, or the like. Main surface 43 of first heat transport member 40 is constituted by the main surface of heat transport portion 45 that faces main surface 34 of metal base substrate 30, the main surface of heat transport portion 46 that faces main surface 34 of metal base substrate 30, and the main surface of heat transport portion 47 that faces main surface 34 of metal base substrate 30. Heat transport portion 47 is also thermally connected to cooler 50. Heat transport portion 47 is fixed to cooler 50 by caulking, pressure welding, soldering, brazing, bonding, welding, or the like.

In a plan view of main surface 33, heat transport portion 47 also extends from end surface 32 of metal base substrate 30 to end surface 31 of metal base substrate 30. A distal end surface of heat transport portion 47 with respect to cooler 50 may be flush with end surface 31 of metal base substrate 30. A proximal end surface of heat transport portion 47 with respect to cooler 50 may be flush with end surface 32 of metal base substrate 30. End surface 41 of first heat transport member 40 is constituted by the distal end surface of heat transport portion 45 with respect to cooler 50, the distal end surface of heat transport portion 46 with respect to cooler 50, and the distal end surface of heat transport portion 47 with respect to cooler 50. End surface 42 of first heat transport member 40 is constituted by the proximal end surface of heat transport portion 45 with respect to cooler 50, the proximal end surface of heat transport portion 46 with respect to cooler 50, and the proximal end surface of heat transport portion 47 with respect to cooler 50.

In the plan view of main surface 33, a part of first heat transport member 40 overlaps the plurality of circuit components 21, 22, and 23. For example, in the plan view of main surface 33, heat transport portion 47 overlaps the plurality of circuit components 21, 22, and 23.

Metal support member 60 supports also heat transport portion 47, Specifically, main surface 63 is provided with a groove 67. Heat transport portion 47 is accommodated in groove 67. Main surface 63 of metal support member 60 may be flush with the main surface of heat transport portion 47 that faces main surface 34 of metal base substrate 30. Heat transport portion 47 is also thermally connected to metal support member 60. Heat transport portion 47 is fixed to metal support member 60 by caulking, pressure welding, soldering, brazing, bonding, welding, or the like.

In the plan view of main surface 33, heat transport portion 45 includes a side surface 45s facing the plurality of circuit components 21, 22, and 23. In the plan view of main surface 33, heat transport portion 46 includes a side surface 46s facing the plurality of circuit components 21, 22, and 23. In the plan view of main surface 33, heat transport portions 45 and 46 may be arranged symmetrically with respect to beat transport portion 47. In the plan view of main surface 33, heat transport portions 45 and 46 may be arranged symmetrically with respect to the plurality of circuit components 21, 22, and 23.

In the plan view of main surface 33, the distance between heat transport portion 45 and the plurality of circuit components 21, 22, and 23 decreases with an increase in distance from cooler 50. Specifically, in the plan view of main surface 33, side surface 45s of heat transport portion 45 approaches the plurality of circuit components 21, 22, and 23 with an increase in distance from cooler 50. In the plan view of main surface 33, side surface 45s of heat transport portion 45 is inclined with respect to the direction (for example, the z direction) in which the plurality of circuit components 21, 22, and 23 are arranged. In the plan view of main surface 33, in the direction (for example, the x direction) perpendicular to the direction (for example, the z direction) in which the plurality of circuit components 21, 22, and 23 are arranged, the distance between circuit component 22 and heat transport portion 45 is shorter than the distance between circuit component 23 and heat transport portion 45. In the plan view of main surface 33, in the direction (for example, the x direction) perpendicular to the direction (for example, the z direction) in which the plurality of circuit components 21, 22, and 23 are arranged, the distance between circuit component 21 and heat transport portion 45 is shorter than the distance between circuit component 22 and heat transport portion 45.

In the plan view of main surface 33, the distance between heat transport portion 46 and the plurality of circuit components 21, 22, and 23 decreases with an increase in distance from cooler 50. Specifically, in the plan view of main surface 33, side surface 46s of heat transport portion 46 approaches the plurality of circuit components 21, 22, and 23 with an increase in distance from cooler 50. In the plan view of main surface 33, side surface 46s of heat transport portion 46 is inclined with respect to the direction (for example, the z direction) in which the plurality of circuit components 21, 22, and 23 are arranged. In the plan view of main surface 33, in the direction (for example, the x direction) perpendicular to the direction (for example, the z direction) in which the plurality of circuit components 21, 22, and 23 are arranged, the distance between circuit component 22 and heat transport portion 46 is shorter than the distance between circuit component 23 and heat transport portion 46. In the plan view of main surface 33, in the direction (for example, the x direction) perpendicular to the direction (for example, the z direction) in which the plurality of circuit components 21, 22, and 23 are arranged, the distance between circuit component 21 and heat transport portion 46 is shorter than the distance between circuit component 22 and heat transport portion 46.

In the plan view of main surface 33, in the arrangement direction (for example, the z direction) of the plurality of circuit components 21, 22, and 23, the lengths of the heat transfer paths from the circuit components to cooler 50 increase with an increase in distance from cooler 50. On the other hand, in the plan view of main surface 33, in the direction (for example, the x direction) perpendicular to the arrangement direction (for example, the z direction) of the plurality of circuit components 21, 22, and 23, the distance between the circuit components and at least one (for example, heat transport portions 45 and 46) of the plurality of heat transport portions 45, 46, and 47 decreases with an increase in distance from cooler 50. Thus, the difference decreases between: the thermal resistance of the heat transfer path extending to cooler 50 from the circuit component (for example, circuit component 21) disposed farther from cooler 50; and the thermal resistance of the heat transfer path extending to cooler 50 from the circuit component (for example, circuit component 23) disposed closer to cooler 50.

In a modification of the present embodiment, in the plan view of main surface 33, heat transport portions 45 and 46 may overlap at least one of circuit components 21, 22, and 23.

In addition to the effects of power conversion apparatus 1d of the fourth embodiment, the following effects of power conversion apparatus 1f of the present embodiment will be described.

In power conversion apparatus 1f, first heat transport member 40 includes the plurality of heat transport portions 45, 46, and 47. Each of the plurality of heat transport portions 45, 46, and 47 is thermally connected to metal base substrate 30 and cooler 50. The distance between the plurality of circuit components 21, 22, and 23 and at least one (for example, heat transport portions 45 and 46) of the plurality of heat transport portions 45, 46, and 47 decreases with an increase in distance from cooler 50.

Thus, the difference decreases between: the thermal resistance of the heat transfer path extending to cooler 50 from the circuit component (for example, circuit component 21) disposed farther from cooler 50; and the thermal resistance of the heat transfer path extending to cooler 50 from the circuit component (for example, circuit component 23) disposed closer to cooler 50. Power conversion apparatus 1f can more uniformly cool the plurality of circuit components 21, 22, and 23. As a circuit component (for example, circuit component 21) disposed farther from cooler 50 among the plurality of circuit components 21, 22, and 23, a circuit component that generates a larger amount of heat can be adopted. The degree of freedom of arrangement of the plurality of circuit components 21, 22, and 23 is improved. The thermal design of power conversion apparatus 1f is facilitated.

Power conversion apparatus 1f includes a larger number of heat transport portions 45, 46, and 47. Thus, the thermal resistance of the heat transfer path from each of the plurality of circuit components 21, 22, and 23 to cooler 50 is reduced. The plurality of circuit components 21, 22, and 23 are efficiently cooled by cooler 50. Cooler 50 can be reduced in size.

In power conversion apparatus 1f, in the plan view of the first main surface (main surface 33), the side surface (for example, side surfaces 45s and 46s) of at least one (for example, heat transport portions 45 and 46) of the plurality of heat transport portions 45, 46, and 47 that faces the plurality of circuit components 21, 22, and 23 approaches the plurality of circuit components 21, 22, and 23 with an increase in distance from cooler 50.

Thus, the difference decreases between: the thermal resistance of the heat transfer path extending to cooler 50 from the circuit component (for example, circuit component 21) disposed farther from cooler 50; and the thermal resistance of the heat transfer path extending to cooler 50 from the circuit component (for example, circuit component 23) disposed closer to cooler 50, Power conversion apparatus 1f can more uniformly cool the plurality of circuit components 21, 22, and 23. As a circuit component (for example, circuit component 21) disposed farther from cooler 50 among the plurality of circuit components 21, 22, and 23, a circuit component that generates a larger amount of heat can be adopted. The degree of freedom of arrangement of the plurality of circuit components 21, 22, and 23 is improved. The thermal design of power conversion apparatus 1f is facilitated.

In power conversion apparatus 1f, in the plan view of the first main surface (main surface 33), the plurality of circuit components 21, 22, and 23 are arranged in the direction (for example, the-z direction) away from cooler 50. In the plan view of the first main surface, at least one (for example, heat transport portions 45 and 46) of the plurality of heat transport portions 45, 46, and 47 is inclined with respect to the direction in which the plurality of circuit components 21, 22, and 23 are arranged.

Thus, the difference decreases between: the thermal resistance of the heat transfer path extending to cooler 50 from the circuit component (for example, circuit component 21) disposed farther from cooler 50; and the thermal resistance of the heat transfer path extending to cooler 50 from the circuit component (for example, circuit component 23) disposed closer to cooler 50. As a circuit component (for example, circuit component 21) disposed farther from cooler 50 among the plurality of circuit components 21, 22, and 23, a circuit component that generates a larger amount of heat can be adopted. The degree of freedom of arrangement of the plurality of circuit components 21, 22, and 23 is improved. The thermal design of power conversion apparatus 1f is facilitated.

### Seventh Embodiment

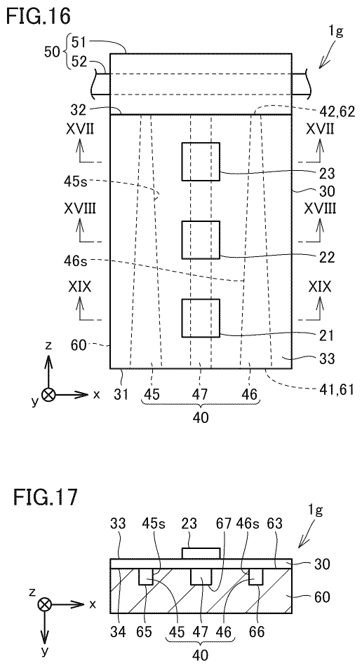

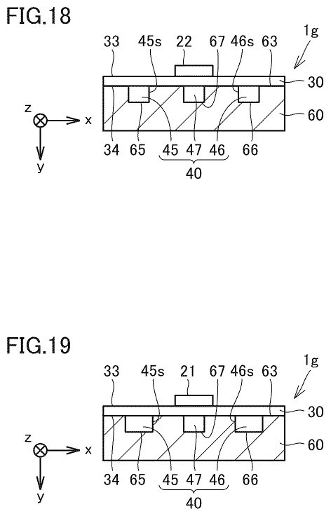

Referring to FIGS. 16 to 19, a power conversion apparatus 1g according to the seventh embodiment will be described. Power conversion apparatus 1g of the present embodiment has the same configuration as that of power conversion apparatus 1f of the sixth embodiment, except mainly for the following points.

In a plan view of main surface 33, the width of heat transport portion 45 increases with an increase in distance from cooler 50. Side surface 45s of heat transport portion 45 is inclined with respect to the direction (for example, the z direction) in which the plurality of circuit components 21, 22, and 23 are arranged. Thus, in the plan view of main surface 33, the distance between heat transport portion 45 and the plurality of circuit components 21, 22, and 23 decreases with an increase in distance from cooler 50. In the plan view of main surface 33, side surface 45% of heat transport portion 45 approaches the plurality of circuit components 21, 22, and 23 with an increase in distance from cooler 50.

In the plan view of main surface 33, the width of heat transport portion 46 increases with an increase in distance from cooler 50. Side surface 46s of heat transport portion 46 is inclined with respect to the direction (for example, the z direction) in which the plurality of circuit components 21, 22, and 23 are arranged. Thus, in the plan view of main surface 33, the distance between heat transport portion 46 and the plurality of circuit components 21, 22, and 23 decreases with an increase in distance from cooler 50. In the plan view of main surface 33, side surface 46s of heat transport portion 46 approaches the plurality of circuit components 21, 22, and 23 with an increase in distance from cooler 50.

In the plan view of main surface 33, in the arrangement direction (for example, the z direction) of the plurality of circuit components 21, 22, and 23, the lengths of the heat transfer paths from the circuit components to cooler 50 increase with an increase in distance from cooler 50. On the other hand, in the plan view of main surface 33, in the direction (for example, the x direction) perpendicular to the arrangement direction (for example, the z direction) of the plurality of circuit components 21, 22, and 23, the distance between the circuit components and at least one (for example, heat transport portions 45 and 46) of the plurality of heat transport portions 45, 46, and 47 decreases with an increase in distance from cooler 50. Thus, the difference decreases between: the thermal resistance of the heat transfer path extending to cooler 50 from the circuit component (for example, circuit component 21) disposed farther from cooler 50; and the thermal resistance of the heat transfer path extending to cooler 50 from the circuit component (for example, circuit component 23) disposed closer to cooler 50.

Power conversion apparatus 1g of the present embodiment has the following effects similar to those of power conversion apparatus 1f of the sixth embodiment.

In power conversion apparatus 1g, in the plan view of the first main surface (main surface 33), the width of at least one (for example, heat transport portions 45 and 46) of the plurality of heat transport portions 45, 46, and 47 increases with an increase in distance from cooler 50.

Thus, the difference decreases between: the thermal resistance of the heat transfer path extending to cooler 50 from the circuit component (for example, circuit component 21) disposed farther from cooler 50; and the thermal resistance of the heat transfer path extending to cooler 50 from the circuit component (for example, circuit component 23) disposed closer to cooler 50. Power conversion apparatus 1g can more uniformly cool the plurality of circuit components 21, 22, and 23. As a circuit component (for example, circuit component 21) disposed farther from cooler 50 among the plurality of circuit components 21, 22, and 23, a circuit component that generates a larger amount of heat can be adopted. The degree of freedom of arrangement of the plurality of circuit components 21, 22, and 23 is improved. The thermal design of power conversion apparatus 1g is facilitated.

In power conversion apparatus 1g, in the plan view of the first main surface (main surface 33), the plurality of circuit components 21, 22, and 23 are arranged in the direction (the-z direction) away from cooler 50. In the plan view of the first main surface, the side surface (for example, side surfaces 45s and 46s) of at least one (for example, heat transport portions 45 and 46) of the plurality of heat transport portions 45, 46, and 47 is inclined with respect to the direction in which the plurality of circuit components 21, 22, and 23 are arranged.

Thus, the difference decreases between: the thermal resistance of the heat transfer path extending to cooler 50 from the circuit component (for example, circuit component 21) disposed farther from cooler 50; and the thermal resistance of the heat transfer path extending to cooler 50 from the circuit component (for example, circuit component 23) disposed closer to cooler 50. Power conversion apparatus 1g can more uniformly cool the plurality of circuit components 21, 22, and 23. As a circuit component (for example, circuit component 21) disposed farther from cooler 50 among the plurality of circuit components 21, 22, and 23, a circuit component that generates a larger amount of heat can be adopted. The degree of freedom of arrangement of the plurality of circuit components 21, 22, and 23 is improved. The thermal design of power conversion apparatus 1g is facilitated.

### Eighth Embodiment

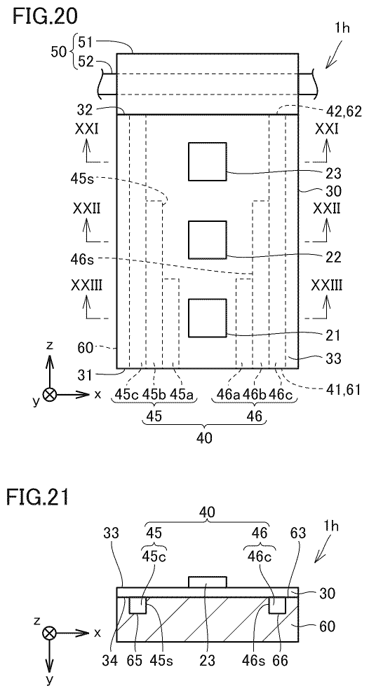

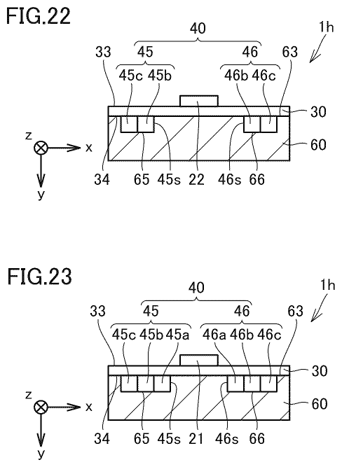

Referring to FIGS. 20 to 23, a power conversion apparatus 1h according to the eighth embodiment will be described. Power conversion apparatus 1h of the present embodiment has the same configuration as that of power conversion apparatus 1g of the seventh embodiment, except mainly for the following points.

In a plan view of main surface 33, side surface 45s of heat transport portion 45 has a stepped shape. Thus, in the plan view of main surface 33, the width of heat transport portion 45 increases with an increase in distance from cooler 50. In the plan view of main surface 33, the distance between heat transport portion 45 and the plurality of circuit components 21, 22, and 23 decreases with an increase in distance from cooler 50. In the plan view of main surface 33, side surface 45s of heat transport portion 45 approaches the plurality of circuit components 21, 22, and 23 with an increase in distance from cooler 50.

Specifically, heat transport portion 45 includes heat transport elements 45a, 45b, and 45c. In the plan view of main surface 33, heat transport element 45a faces circuit component 21, but does not face circuit components 22 and 23. In the plan view of main surface 33, heat transport element 45b faces circuit components 21 and 22, but does not face circuit component 23. In the plan view of main surface 33, heat transport element 45c faces circuit components 21, 22, and 23.

In the plan view of main surface 33, heat transport element 45c is longer than heat transport elements 45a and 45b. In the plan view of main surface 33, heat transport element 45b is longer than heat transport element 45a. A distal end surface of heat transport element 45a with respect to cooler 50 may be flush with end surface 31 of metal base substrate 30. A distal end surface of heat transport element 45b with respect to cooler 50 may be flush with end surface 31 of metal base substrate 30. A distal end surface of heat transport element 45c with respect to cooler 50 may be flush with end surface 31 of metal base substrate 30. A proximal end surface of heat transport element 45a with respect to cooler 50 is spaced apart from end surface 32 of metal base substrate 30. A proximal end surface of heat transport element 45b with respect to cooler 50 is spaced apart from end surface 32 of metal base substrate 30. A proximal end surface of heat transport element 45e with respect to cooler 50 may be flush with end surface 32 of metal base substrate 30.

In the plan view of main surface 33, in the direction (for example, the x direction) perpendicular to the direction (for example, the z direction) in which the plurality of circuit components 21, 22, and 23 are arranged, heat transport element 45a is disposed closest to the plurality of circuit components 21, 22, and 23 among heat transport elements 45a, 45b, and 45c. In the plan view of main surface 33, in the direction (for example, the x direction) perpendicular to the direction (for example, the z direction) in which the plurality of circuit components 21, 22, and 23 are arranged, heat transport element 45c is disposed farthest from the plurality of circuit components 21, 22, and 23 among heat transport elements 45a, 45b, and 45c. In the plan view of main surface 33, in the direction (for example, the x direction) perpendicular to the direction (for example, the z direction) in which the plurality of circuit components 21, 22, and 23 are arranged, heat transport element 45b is disposed between heat transport elements 45a and 45c. Heat transport element 45b is thermally connected to heat transport elements 45a and 45c. Heat transport elements 45a, 45b, and 45c may be integrated as a single component.

In the plan view of main surface 33, side surface 46s of heat transport portion 46 has a stepped shape. Thus, in the plan view of main surface 33, the width of heat transport portion 46 increases with an increase in distance from cooler 50. In the plan view of main surface 33, the distance between heat transport portion 46 and the plurality of circuit components 21, 22, and 23 decreases with an increase in distance from cooler 50. In the plan view of main surface 33, side surface 46s of heat transport portion 46 approaches the plurality of circuit components 21, 22, and 23 with an increase in distance from cooler 50.

Specifically, heat transport portion 46 includes heat transport elements 46a, 46b, and 46c. In the plan view of main surface 33, heat transport element 46a faces circuit component 21, but does not face circuit components 22 and 23. In the plan view of main surface 33, heat transport element 46b faces circuit components 21 and 22, but does not face circuit component 23. In the plan view of main surface 33, heat transport element 46c faces circuit components 21, 22, and 23.

In the plan view of main surface 33, heat transport element 46c is longer than heat transport elements 46a and 46b. In the plan view of main surface 33, heat transport element 46b is longer than heat transport element 46a. A distal end surface of heat transport element 46a with respect to cooler 50 may be flush with end surface 31 of metal base substrate 30. A distal end surface of heat transport element 46b with respect to cooler 50 may be flush with end surface 31 of metal base substrate 30. A distal end surface of heat transport element 46c with respect to cooler 50 may be flush with end surface 31 of metal base substrate 30. A proximal end surface of heat transport element 46a with respect to cooler 50 is spaced apart from end surface 32 of metal base substrate 30. A proximal end surface of heat transport element 46b with respect to cooler 50 is spaced apart from end surface 32 of metal base substrate 30. A proximal end surface of heat transport element 46c with respect to cooler 50 may be flush with end surface 32 of metal base substrate 30.

In the plan view of main surface 33, in the direction (for example, the x direction) perpendicular to the direction (for example, the z direction) in which the plurality of circuit components 21, 22, and 23 are arranged, heat transport element 46a is disposed closest to the plurality of circuit components 21, 22, and 23 among heat transport elements 46a, 46b, and 46c. In the plan view of main surface 33, in the direction (for example, the x direction) perpendicular to the direction (for example, the z direction) in which the plurality of circuit components 21, 22, and 23 are arranged, heat transport element 46c is disposed farthest from the plurality of circuit components 21, 22, and 23 among heat transport elements 46a, 46b, and 46c. In the plan view of main surface 33, in the direction (for example, the x direction) perpendicular to the direction (for example, the z direction) in which the plurality of circuit components 21, 22, and 23 are arranged, heat transport element 46b is disposed between heat transport elements 46a and 46c. Heat transport element 46b is thermally connected to heat transport elements 46a and 46c. Heat transport elements 46a, 46b, and 46c may be integrated as a single component.

In the plan view of main surface 33, in the arrangement direction (for example, the z direction) of the plurality of circuit components 21, 22, and 23, the lengths of the heat transfer paths from the circuit components to cooler 50 increase with an increase in distance from cooler 50. On the other hand, each of side surfaces 45s and 46s of heat transport portions 45 and 46 has a stepped shape. In the plan view of main surface 33, in the direction (for example, the x direction) perpendicular to the arrangement direction (for example, the z direction) of the plurality of circuit components 21, 22, and 23, the distance between the circuit components and at least one (for example, heat transport portions 45 and 46) of the plurality of heat transport portions 45 and 46 decreases with an increase in distance from cooler 50. Thus, the difference decreases between: the thermal resistance of the heat transfer path extending to cooler 50 from the circuit component (for example, circuit component 21) disposed farther from cooler 50; and the thermal resistance of the heat transfer path extending to cooler 50 from the circuit component (for example, circuit component 23) disposed closer to cooler 50.

Power conversion apparatus 1h of the present embodiment has the following effects similar to those of power conversion apparatus 1g of the seventh embodiment.

In power conversion apparatus 1h, in the plan view of the first main surface (main surface 33), the side surface (for example, side surfaces 45s and 46s) of at least one (for example, heat transport portions 45 and 46) of the plurality of heat transport portions 45 and 46 has a stepped shape.

Thus, the difference decreases between: the thermal resistance of the heat transfer path extending to cooler 50 from the circuit component (for example, circuit component 21) disposed farther from cooler 50; and the thermal resistance of the heat transfer path extending to cooler 50 from the circuit component (for example, circuit component 23) disposed closer to cooler 50. Power conversion apparatus 1h can more uniformly cool the plurality of circuit components 21, 22, and 23. As a circuit component (for example, circuit component 21) disposed farther from cooler 50 among the plurality of circuit components 21, 22, and 23, a circuit component that generates a larger amount of heat can be adopted. The degree of freedom of arrangement of the plurality of circuit components 21, 22, and 23 is improved. The thermal design of power conversion apparatus 1h is facilitated.

### Ninth Embodiment

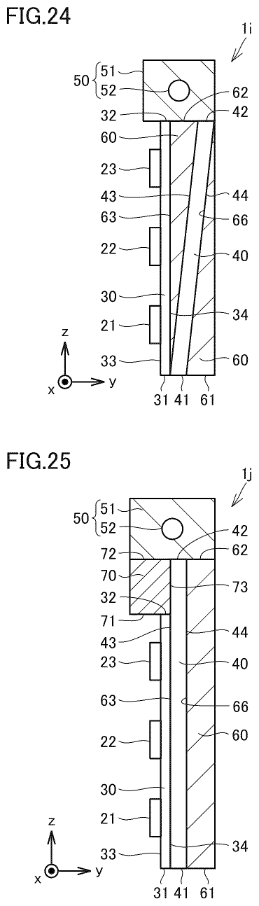

Referring to FIG. 24, a power conversion apparatus 1i according to the ninth embodiment will be described. Power conversion apparatus 1i of the present embodiment has the same configuration as that of power conversion apparatus 1d of the fourth embodiment, except mainly for the following points.

The distance between metal base substrate 30 and first heat transport member 40 decreases with an increase in distance from cooler 50. Thus, the distance between first heat transport member 40 and the plurality of circuit components 21, 22, and 23 decreases with an increase in distance from cooler 50.

Specifically, the distance between metal base substrate 30 and first heat transport member 40 in the thickness direction (for example, the y direction) of metal base substrate 30 decreases with an increase in distance from cooler 50. The distance between circuit component 22 and first heat transport member 40 is shorter than the distance between circuit component 23 and first heat transport member 40. The distance between circuit component 21 and first heat transport member 40 is shorter than the distance between circuit component 22 and first heat transport member 40.

In a plan view of main surface 33, in the arrangement direction (for example, the z direction) of the plurality of circuit components 21, 22, and 23, the lengths of the heat transfer paths from the circuit components to cooler 50 increase with an increase in distance from cooler 50. On the other hand, in the thickness direction (for example, the y direction) of metal base substrate 30, the distance between the circuit components and first heat transport member 40 decreases with an increase in distance from cooler 50. Thus, the difference decreases between: the thermal resistance of the heat transfer path extending to cooler 50 from the circuit component (for example, circuit component 21) disposed farther from cooler 50; and the thermal resistance of the heat transfer path extending to cooler 50 from the circuit component (for example, circuit component 23) disposed closer to cooler 50.

Power conversion apparatus 1i of the present embodiment has the following effects in addition to the effects of power conversion apparatus 1d of the fourth embodiment.

In power conversion apparatus 1i, the distance between metal base substrate 30 and first heat transport member 40 decreases with an increase in distance from cooler 50.

Thus, the difference decreases between: the thermal resistance of the heat transfer path extending to cooler 50 from the circuit component (for example, circuit component 21) disposed farther from cooler 50; and the thermal resistance of the beat transfer path extending to cooler 50 from the circuit component (for example, circuit component 23) disposed closer to cooler 50. Power conversion apparatus 1i can more uniformly cool the plurality of circuit components 21, 22, and 23. As a circuit component (for example, circuit component 21) disposed farther from cooler 50 among the plurality of circuit components 21, 22, and 23, a circuit component that generates a larger amount of heat can be adopted. The degree of freedom of arrangement of the plurality of circuit components 21, 22, and 23 is improved. The thermal design of power conversion apparatus 1i is facilitated.

### Tenth Embodiment

Referring to FIG. 25, a power conversion apparatus 1j according to the tenth embodiment will be described. Power conversion apparatus 1j of the present embodiment has the same configuration as that of power conversion apparatus 1d of the fourth embodiment, except mainly for the following points.

Power conversion apparatus 1j further includes a metal member 70.

Metal member 70 includes an end surface 71, an end surface 72 opposite to end surface 71, and a main surface 73. End surface 71 is a distal end surface of metal member 70 with respect to cooler 50. End surface 71 faces end surface 32 of metal base substrate 30. End surface 72 is a proximal end surface of metal member 70 with respect to cooler 50. End surface 72 faces cooler 50. Each of end surfaces 71 and 72 is larger than end surface 32 of metal base substrate 30. Each of end surfaces 71 and 72 may be larger than end surface 42 of first heat transport member 40. Main surface 73 is connected to end surfaces 71 and 72. Main surface 73 is an end surface of metal member 70 in its thickness direction (for example, the y direction). Main surface 73 faces main surface 43 of first heat transport member 40 and main surface 63 of metal support member 60.

Metal base substrate 30 is thermally connected to cooler 50 with metal member 70 being interposed therebetween. Metal member 70 is thermally connected to metal base substrate 30, first heat transport member 40, metal support member 60, and cooler 50. Specifically, end surface 71 of metal member 70 is thermally connected to end surface 32 of metal base substrate 30. End surface 72 of metal member 70 is thermally connected to cooler 50. Main surface 73 of metal member 70 is thermally connected to main surface 43 of first heat transport member 40 and main surface 63 of metal support member 60.

Metal member 70 is fixed to metal base substrate 30, first heat transport member 40, metal support member 60, and cooler 50. For example, end surface 71 of metal member 70 is fixed to end surface 32 of metal base substrate 30 by caulking, pressure welding, soldering, brazing, bonding, welding, or the like. End surface 72 of metal member 70 is fixed to cooler 50 by caulking, pressure welding, soldering. brazing, bonding, welding, or the like. Main surface 73 of metal member 70 is fixed to main surface 43 of first heat transport member 40 and main surface 63 of metal support member 60 by caulking, pressure welding, soldering, brazing, bonding, welding, or the like.

The thermal conductivity of metal member 70 is equal to or higher than the thermal conductivity of metal plate 36. Metal member 70 is made, for example, of metal such as copper, iron, aluminum, an iron alloy, or an aluminum alloy. Metal member 70 may be made of the same material as that of metal support member 60. Metal member 70 has a thermal conductivity, for example, of 1.0 W/(m·K) or more. Metal member 70 may have a thermal conductivity of 10.0 W/(m·K) or more, or may have a thermal conductivity of 100.0 W/(m·K) or more. Metal member 70 transfers the heat generated in the plurality of circuit components 21, 22, and 23 to cooler 50.

Metal member 70 may be a rigid member such as a metal block. Metal member 70 may be larger in cross-sectional area than metal base substrate 30. The cross-sectional area of metal member 70 is an area of the cross section of metal member 70 that is taken along a plane perpendicular to the direction (for example, the z direction) in which the heat generated in the plurality of circuit components 21, 22, and 23 is mainly transferred. Metal member 70 may be integrated with metal support member 60, or metal member 70 and metal support member 60 may be a single member.

In a modification of the present embodiment, main surface 73 of metal member 70 may be connected to at least one of main surface 43 of first heat transport member 40 or main surface 63 of metal support member 60.

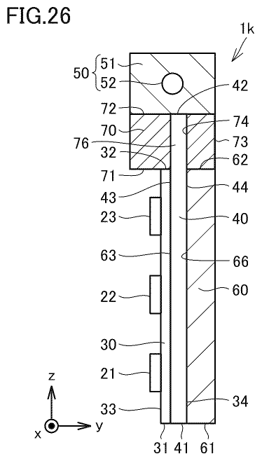

Referring to FIG. 26, in a power conversion apparatus 1k of another modification of the present embodiment, metal member 70 is disposed between metal base substrate 30 and cooler 50, and disposed also between metal support member 60 and cooler 50. End surface 62 of metal support member 60 may be flush with end surface 32 of metal base substrate 30. Main surface 73 of metal member 70 may be flush with the main surface of metal support member 60 on the side opposite to main surface 63. Metal support member 60 is thermally connected to cooler 50 with metal member 70 being interposed therebetween. Specifically, end surface 71 of metal member 70 faces end surface 32 of metal base substrate 30 and end surface 62 of metal support member 60, and is thermally connected to end surface 32 of metal base substrate 30 and end surface 62 of metal support member 60. Metal member 70 is fixed to metal base substrate 30 and metal support member 60 by caulking, pressure welding, soldering, brazing, bonding, welding, or the like.

Metal member 70 is provided with a hole 74. Hole 74 may be a through hole extending from end surface 71 to end surface 72, or may be a blind hole formed in end surface 71 and not extending to end surface 72. First heat transport member 40 includes a protrusion 76 protruding from end surface 32 of metal base substrate 30 in a plan view of main surface 33. Protrusion 76 includes end surface 42. Protrusion 76 is inserted into hole 74 and thermally connected to metal member 70. Protrusion 76 is fixed to metal member 70 by fitting, caulking, pressure welding, soldering, brazing, bonding, welding, or the like.

Metal member 70 may be a single metal component or may be formed by combining a plurality of metal components.

In addition to the effects of power conversion apparatus 1d of the fourth embodiment, the following effects of power conversion apparatuses 1j and 1k of the present embodiment will be described.

Power conversion apparatuses 1j and 1k each further include metal member 70 thermally connected to cooler 50. The first end surface (end surface 32) is thermally connected to metal member 70.

Thus, the thermal resistance of the heat transfer path from each of the plurality of circuit components 21, 22, and 23 to cooler 50 is reduced. The plurality of circuit components 21, 22, and 23 are efficiently cooled by cooler 50. Cooler 50 can be reduced in size, In each of power conversion apparatuses 1j and 1k, end surface 72 of metal member 70 that faces cooler 50 is larger than the first end surface (end surface 32).

Thus, the thermal resistance of the heat transfer path from each of the plurality of circuit components 21, 22, and 23 to cooler 50 is reduced. The plurality of circuit components 21, 22, and 23 are efficiently cooled by cooler 50. Cooler 50 can be reduced in size.

### Eleventh Embodiment

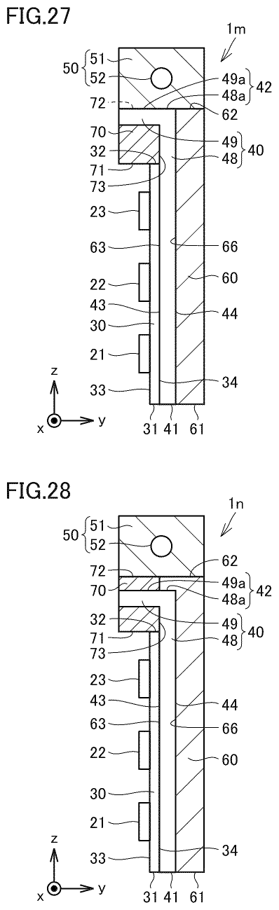

Referring to FIG. 27, a power conversion apparatus 1m according to the eleventh embodiment will be described. Power conversion apparatus 1m of the present embodiment has the same configuration as that of power conversion apparatus 1j of the tenth embodiment, except mainly for the following points.

First heat transport member 40 includes heat transport portions 48 and 49.

Heat transport portion 48 includes main surfaces 43 and 44 of first heat transport member 40. Heat transport portion 48 includes end surface 41 and an end surface 48a of first beat transport member 40. End surface 41 of first heat transport member 40 is a distal end surface of heat transport portion 48 with respect to cooler 50. End surface 48a is a proximal end surface of heat transport portion 48 with respect to cooler 50. End surface 48a faces cooler 50. Heat transport portion 48 includes end surface 42 of first heat transport member 40. End surface 48a is a part of end surface 42 of first heat transport member 40. End surface 48a of heat transport portion 48 may be flush with end surface 62 of metal support member 60 and end surface 72 of metal member 70.

Heat transport portion 48 is thermally connected to metal base substrate 30, metal member 70, cooler 50, and metal support member 60. Heat transport portion 48 is fixed to metal base substrate 30, metal member 70, cooler 50, and metal support member 60 by caulking, pressure welding, soldering, brazing, bonding, welding, or the like.

Heat transport portion 49 is connected to heat transport portion 48. Heat transport portion 49 protrudes from main surface 43 of first heat transport member 40 in the thickness direction (for example, the y direction) of metal base substrate 30. Heat transport portion 49 includes an end surface 49a. End surface 49a is a proximal end surface of heat transport portion 49 with respect to cooler 50. End surface 49a faces cooler 50. Heat transport portion 49 includes end surface 42 of first heat transport member 40. End surface 49a is a part of end surface 42 of first heat transport member 40. End surface 49a of heat transport portion 49 may be flush with end surface 62 of metal support member 60 and end surface 72 of metal member 70. End surface 42 of first heat transport member 40 is constituted by end surfaces 48a and 49a.

Heat transport portion 49 is thermally connected to metal member 70 and cooler 50. Heat transport portion 49 is fixed to metal member 70 and cooler 50 by caulking, pressure welding, soldering, brazing, bonding, welding, or the like.

Referring to FIG. 28, a power conversion apparatus 1n according to a modification of the present embodiment will be described. In power conversion apparatus 1n, first heat transport member 40 is thermally connected to cooler 50 with metal member 70 and metal support member 60 being interposed therebetween. A part of metal member 70 and a part of metal support member 60 are located between end surface 42 of first heat transport member 40 and cooler 50. End surface 42 of first heat transport member 40 is separated from cooler 50 by metal member 70 and metal support member 60.

Heat transport portion 48 is thermally connected to metal base substrate 30, metal member 70, and metal support member 60. Heat transport portion 48 is fixed to metal base substrate 30, metal member 70, and metal support member 60 by caulking, pressure welding, soldering, brazing, bonding, welding, or the like. Heat transport portion 48 is thermally connected to cooler 50 with metal support member 60 being interposed therebetween. Metal support member 60 is located between end surface 48a of heat transport portion 48 and cooler 50.

Heat transport portion 49 is thermally connected to metal member 70. Heat transport portion 49 is fixed to metal member 70 by caulking, fitting, soldering, brazing, bonding, welding, or the like. Metal member 70 is fixed to cooler 50. Heat transport portion 49 is thermally connected to cooler 50 with metal member 70 being interposed therebetween. Metal member 70 is located between end surface 49a of heat transport portion 49 and cooler 50.

In addition to the effects of power conversion apparatus 1j of the tenth embodiment, the following effects of power conversion apparatuses 1m and 1n of the present embodiment will be described.

In each of power conversion apparatuses 1m and 1n, first heat transport member 40 includes a first heat transport portion (heat transport portion 48) including the second main surface (main surface 43) and a second heat transport portion (heat transport portion 49) protruding from the second main surface. The second heat transport portion includes the second end surface (end surface 42) and is thermally connected to cooler 50.

Thus, first heat transport member 40 faces cooler 50 in a wider area. The thermal resistance of the heat transfer path from each of the plurality of circuit components 21, 22, and 23 to cooler 50 is reduced. The plurality of circuit components 21, 22, and 23 are efficiently cooled by cooler 50. Cooler 50 can be reduced in size.

Power conversion apparatuses 1m and 1n each further include metal member 70 thermally connected to cooler 50. The first end surface (end surface 32) and the second heat transport portion (heat transport portion 49) are thermally connected to metal member 70.

Thus, the thermal resistance of the heat transfer path from each of the plurality of circuit components 21, 22, and 23 to cooler 50 is reduced. The plurality of circuit components 21, 22, and 23 are efficiently cooled by cooler 50. Cooler 50 can be reduced in size.

### Twelfth Embodiment

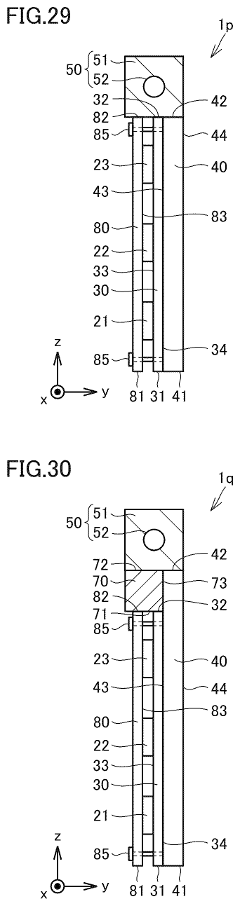

Referring to FIG. 29, a power conversion apparatus 1p according to the twelfth embodiment will be described. Power conversion apparatus 1p of the present embodiment has the same configuration as that of power conversion apparatus 1 of the first embodiment, except mainly for the following points.

Power conversion apparatus 1p further includes a second heat transport member 80 and a fixing member 85.

Similarly to first heat transport member 40, second heat transport member 80 transfers or diffuses the heat generated in the plurality of circuit components 21, 22, and 23 to cooler 50.

Specifically, second heat transport member 80 includes an end surface 81, an end surface 82 opposite to end surface 81, and a main surface 83. End surfaces 81 and 82 are, for example, both end surfaces of second heat transport member 80 in its long-side direction (for example, the z direction). The long-side direction (for example, the z direction) of second heat transport member 80 is not particularly limited, but may be the direction of gravity. End surface 81 is a distal end surface of second heat transport member 80 with respect to cooler 50. End surface 82 is a proximal end surface of second heat transport member 80 with respect to cooler 50. End surface 82 faces cooler 50.

End surface 82 of second heat transport member 80 is thermally connected to cooler 50. End surface 82 of second heat transport member 80 is fixed to cooler 50 by caulking, pressure welding, soldering, brazing, bonding, welding, or the like.

Main surface 83 is connected to end surfaces 81 and 82. Main surface 83 is an end surface of second heat transport member 80 in its thickness direction. Main surface 83 faces the plurality of circuit components 21, 22, and 23 and main surface 33 of metal base substrate 30. Main surface 83 of second heat transport member 80 is thermally connected to the plurality of circuit components 21, 22, and 23. Main surface 83 of second heat transport member 80 is fixed to the plurality of circuit components 21, 22, and 23 by pressure welding, soldering, brazing, bonding, welding, or the like.

The thermal conductivity of second heat transport member 80 is equal to or higher than the thermal conductivity of metal plate 36. Second heat transport member 80 is, for example, a heat pipe, a vapor chamber, a graphite sheet, or a metal plate integrated with any of these components. Second heat transport member 80 is made, for example, of a metal material such as copper, iron, aluminum, an iron alloy, or an aluminum alloy, or carbon. Second heat transport member 80 may be made of the same material as that of first heat transport member 40. Second heat transport member 80 has a thermal conductivity, for example, of 1.0 W/(m·K) or more. Second heat transport member 80 may have a thermal conductivity of 10.0 W/(m·K) or more, or may have a thermal conductivity of 100.0 W/(m·K) or more.

Second heat transport member 80 is fixed to metal base substrate 30 with the use of fixing member 85. Fixing member 85 is, for example, a screw or an adhesive. Second heat transport member 80 presses the plurality of circuit components 21, 22, and 23 toward metal base substrate 30. Thus, the vibration resistance of power conversion apparatus 1p is improved. Deterioration of the plurality of circuit components 21, 22, and 23 can be prevented.

Referring to FIG. 30, a power conversion apparatus 1q according to a modification of the present embodiment will be described. Power conversion apparatus 1q further includes metal member 70 similarly to power conversion apparatus 1j of the tenth embodiment.

End surface 71 of metal member 70 faces end surface 82 of second heat transport member 80. End surface 71 of metal member 70 may be larger than end surface 82 of second heat transport member 80. End surface 72 of metal member 70 faces cooler 50. End surface 72 of metal member 70 may be larger than end surface 82 of second heat transport member 80. Main surface 73 of metal member 70 faces main surface 43 of first heat transport member 40.

Metal member 70 is thermally connected to second heat transport member 80. metal base substrate 30, first heat transport member 40, and cooler 50. Second heat transport member 80 is thermally connected to cooler 50 with metal member 70 being interposed therebetween. End surface 82 of second heat transport member 80 is thermally connected to end surface 71 of metal member 70. End surface 72 of metal member 70 is thermally connected to cooler 50.

Metal member 70 is fixed to second heat transport member 80, metal base substrate 30, first heat transport member 40, and cooler 50. For example, end surface 71 of metal member 70 is fixed to end surface 82 of second heat transport member 80 and end surface 32 of metal base substrate 30 by caulking, pressure welding, soldering, brazing, bonding, welding, or the like. End surface 72 of metal member 70 is fixed to cooler 50 by caulking, pressure welding, soldering, brazing, bonding, welding, or the like. Main surface 73 of metal member 70 is fixed to main surface 43 of first heat transport member 40 by caulking, pressure welding, soldering, brazing, bonding, welding, or the like.

In addition to the effects of power conversion apparatus 1 of the first embodiment, the following effects of power conversion apparatuses 1p and 1q of the present embodiment will be described.

Power conversion apparatuses 1p and 1q each further include second heat transport member 80 including a fifth main surface (main surface 83) and a fifth end surface (end surface 82) connected to the fifth main surface. The fifth main surface is thermally connected to the plurality of circuit components 21, 22, and 23. The fifth end surface is thermally connected to cooler 50.

The heat generated in the plurality of circuit components 21, 22, and 23 is transferred to cooler 50 also through second heat transport member 80 in addition to metal base substrate 30 and first heat transport member 40. Thus, the thermal resistance of the heat transfer path from each of the plurality of circuit components 21, 22, and 23 to cooler 50 is reduced. The plurality of circuit components 21, 22, and 23 are efficiently cooled by cooler 50. Cooler 50 can be reduced in size.

Power conversion apparatus 1q further includes metal member 70 thermally connected to cooler 50. The first end surface (end surface 32) and the fifth end surface (end surface 82) are thermally connected to metal member 70.

Thus, the thermal resistance of the heat transfer path from each of the plurality of circuit components 21, 22, and 23 to cooler 50 is reduced. The plurality of circuit components 21, 22, and 23 are efficiently cooled by cooler 50. Cooler 50 can be reduced in size.

### Thirteenth Embodiment

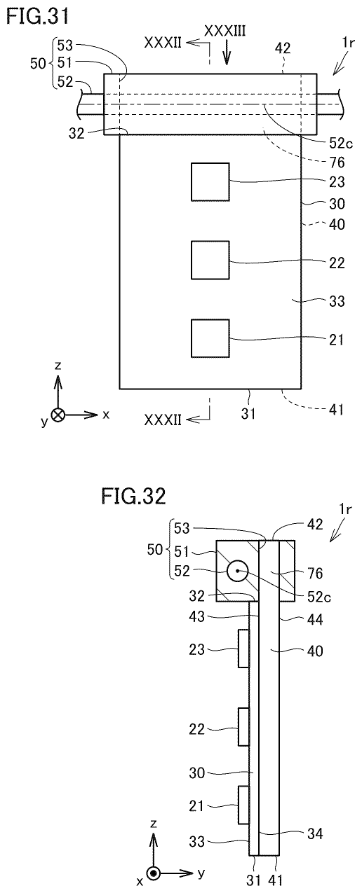

Referring to FIGS. 31 to 33, a power conversion apparatus 1r according to the thirteenth embodiment will be described. Power conversion apparatus 1r of the present embodiment has the same configuration as that of power conversion apparatus 1 of the first embodiment, except mainly for the following points.

Cooler 50 is provided with a hole 53. Hole 53 may be a through hole formed in the surface of cooler 50 that faces end surface 32, or may be a blind hole formed in the surface of cooler 50 that faces end surface 32. The cross-sectional shape of hole 53 (the shape of hole 53 in end surface 32) is, for example, a circle, an ellipse, or a rectangle. First heat transport member 40 includes protrusion 76 protruding from end surface 32 of metal base substrate 30 in a plan view of main surface 33. Protrusion 76 includes end surface 42. When hole 53 is a through hole, end surface 42 may protrude from cooler 50. Protrusion 76 is inserted into hole 53 and thermally connected to cooler 50. Protrusion 76 is fixed to cooler 50 by fitting, caulking, pressure welding, soldering, brazing, bonding, welding, or the like.

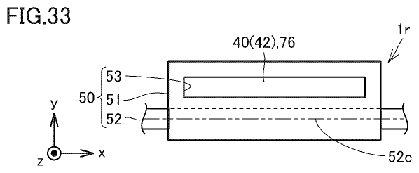

A central axis 52c of the flow path for refrigerant (for example, cooling pipe 52) intersects with the direction (the z direction) in which protrusion 76 is inserted into hole 53. Central axis 52c may be orthogonal to the direction (the z direction) in which protrusion 76 is inserted into hole 53. As shown in FIG. 33, in a plan view in the direction (the z direction) in which protrusion 76 is inserted into hole 53, the flow path for refrigerant is displaced from protrusion 76 in the thickness direction (for example, the y direction) of metal base substrate 30.

As shown in FIG. 31, in the plan view of main surface 33, at least a part of the flow path for refrigerant (for example, cooling pipe 52) may overlap protrusion 76 of first heat transport member 40. In the plan view of main surface 33, first heat transport member 40 may extend to the side opposite to end surface 41 with respect to central axis 52c of the flow path for refrigerant. In the direction (the z direction) in which protrusion 76 is inserted into hole 53, a portion of the flow path for refrigerant (for example, cooling pipe 52) that is provided in heat sink 51 may be disposed between end surfaces 42 and 32.

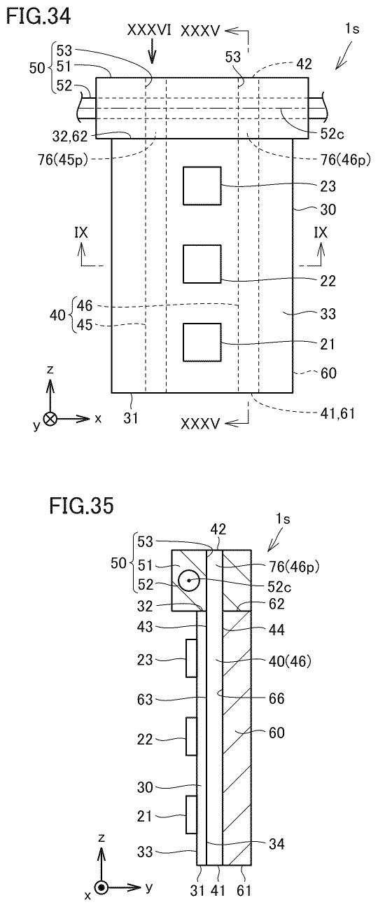

Referring to FIGS. 34 to 36, in a power conversion apparatus 1s according to the first modification of the present embodiment, first heat transport member 40 may be divided into a plurality of heat transport portions 45 and 46, and cooler 50 may be provided with a plurality of holes 53 into which the plurality of heat transport portions 45 and 46 are inserted. Power conversion apparatus 1s has the same configuration as that of power conversion apparatus 1d of the fourth embodiment, except mainly for the following points.

Cooler 50 is provided with the plurality of holes 53. The plurality of holes 53 may be through holes formed in the surface of cooler 50 that faces end surface 32, may be blind holes formed in the surface of cooler 50 that faces end surface 32, or may be a combination of through holes and blind holes. The cross-sectional shapes of the plurality of holes 53 may be different from each other.

First heat transport member 40 includes protrusion 76 protruding from end surface 32 of metal base substrate 30 in a plan view of main surface 33. Protrusion 76 includes end surface 42. Specifically, heat transport portion 45 includes a protruding portion 45p protruding from end surface 32 of metal base substrate 30 in the plan view of main surface 33. Heat transport portion 46 includes a protruding portion 46p protruding from end surface 32 of metal base substrate 30 in the plan view of main surface 33. Protrusion 76 includes protruding portions 45p and 46p. Protruding portions 45p and 46p each include end surface 42. Protruding portions 45p and 46p are inserted into the plurality of holes 53 and thermally connected to cooler 50. Protruding portions 45p and 46p are fixed to cooler 50 by fitting, caulking, pressure welding, soldering, brazing, bonding, welding, or the like.

As shown in FIG. 34. in the plan view of main surface 33, at least a part of the flow path for refrigerant (cooling pipe 52) may overlap protruding portions 45p and 46p. In the plan view of main surface 33, protruding portions 45p and 46p may extend to the side opposite to end surface 41 with respect to central axis 52c of the flow path for refrigerant (for example, cooling pipe 52) in the cooler. In the direction (the z direction) in which the plurality of protruding portions 45p and 46p are inserted into the plurality of holes 53, a portion of the flow path for refrigerant (for example, cooling pipe 52) that is provided in heat sink 51 may be disposed between end surfaces 42 and 32.

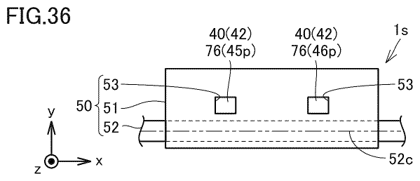

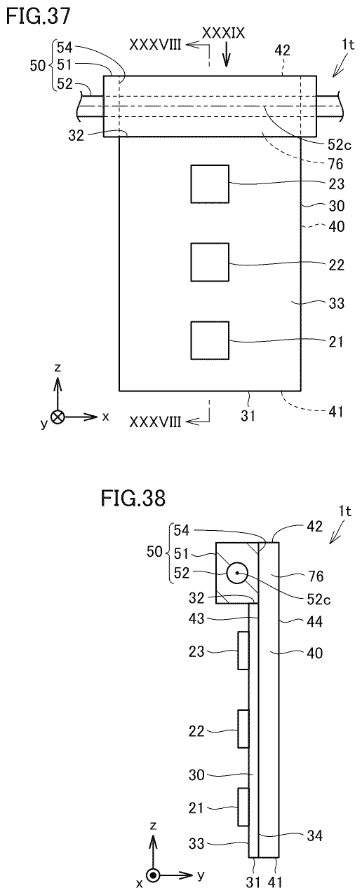

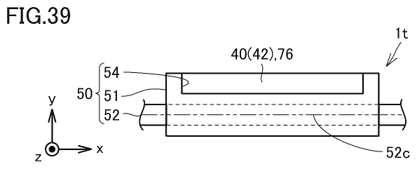

Referring to FIGS. 37 to 39, a power conversion apparatus 1t according to the second modification of the present embodiment is configured in the same manner as power conversion apparatus 1r of the present embodiment, except that a recess 54 is provided in cooler 50 instead of hole 53 (see FIGS. 31 to 33). Recess 54 is formed in the surface of cooler 50 that faces end surface 32. Recess 54 may or may not pass through cooler 50. Protrusion 76 is inserted into recess 54 and thermally connected to cooler 50. Protrusion 76 is fixed to cooler 50 by fitting, caulking, pressure welding, soldering, brazing, bonding, welding, or the like. Central axis 52c of the flow path for refrigerant (for example, cooling pipe 52) intersects with the direction (the z direction) in which protrusion 76 is inserted into recess 54. Central axis 52e may be orthogonal to the direction (the z direction) in which protrusion 76 is inserted into recess 54. As shown in FIG. 36, in a plan view in the direction (the z direction) in which protrusion 76 is inserted into recess 54, the flow path for refrigerant is displaced from protrusion 76 in the thickness direction (for example, the y direction) of metal base substrate 30.

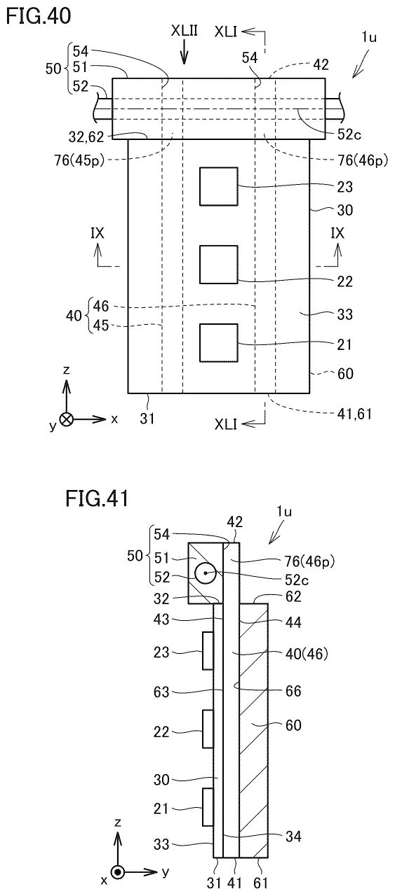

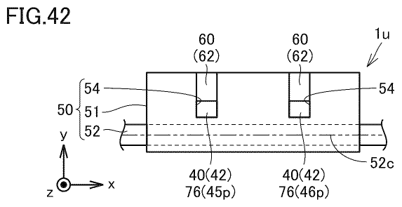

Referring to FIGS. 40 to 42, a power conversion apparatus 1u according to the third modification of the present embodiment is configured in the same manner as power conversion apparatus 1s of the first modification of the present embodiment, except that the plurality of recesses 54 are provided in cooler 50 instead of the plurality of holes 53 (see FIGS. 34 to 36). The plurality of recesses 54 are formed in the surface of cooler 50 that faces end surface 32. The plurality of recesses 54 may or may not pass through cooler 50. Some of the plurality of recesses 54 may pass through cooler 50, and the rest thereof may not pass through cooler 50. Protruding portions 45p and 46p are inserted into the plurality of recesses 54 and thermally connected to cooler 50. Protruding portions 45p and 46p are fixed to cooler 50 by fitting, caulking, pressure welding, soldering, brazing, bonding, welding, or the like.

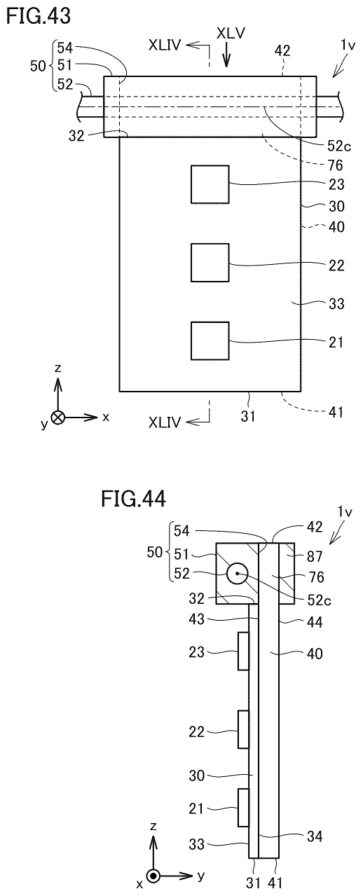

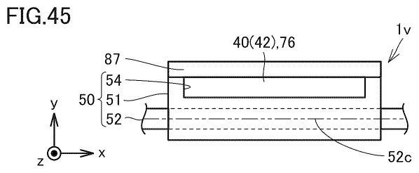

Referring to FIGS. 43 to 45, a power conversion apparatus 1v according to the fourth modification of the present embodiment is configured in the same manner as power conversion apparatus 1t of the second modification of the present embodiment, except that it further includes a fixing plate 87. Fixing plate 87 is fixed to heat sink 51 by caulking, pressure welding, soldering, brazing, bonding, welding, or the like. Fixing plate 87 may be fixed to protrusion 76 of first heat transport member 40 by caulking, pressure welding, soldering, brazing, bonding, welding, or the like. Protrusion 76 is sandwiched between heat sink 51 and fixing plate 87. Fixing plate 87 prevents protrusion 76 from coming off from recess 54. Fixing plate 87 is made, for example, of metal or resin. By forming fixing plate 87 from metal, the thermal resistance of the heat transfer path from each of the plurality of circuit components 21, 22, and 23 to cooler 50 is further reduced.

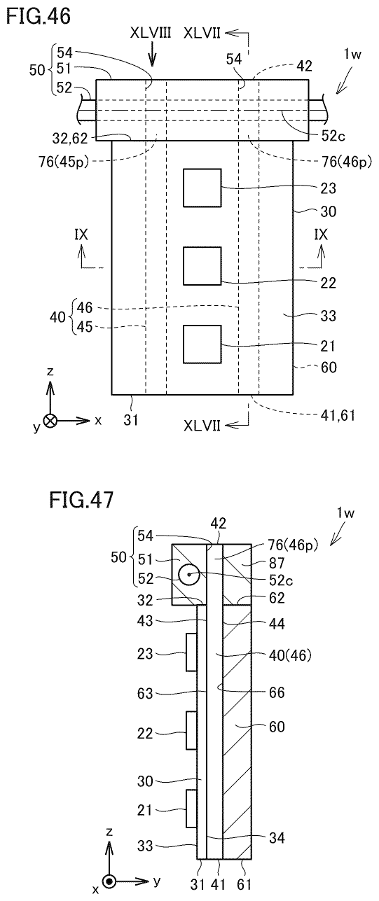

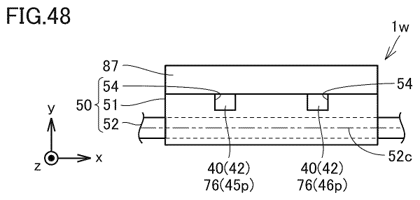

Referring to FIGS. 46 to 48, a power conversion apparatus 1w according to the fifth modification of the present embodiment is configured in the same manner as power conversion apparatus 1u of the third modification of the present embodiment, except that it further includes fixing plate 87. Fixing plate 87 is fixed to heat sink 51 by caulking, pressure welding, soldering, brazing, bonding, welding, or the like. Fixing plate 87 may be fixed to protruding portions 45p and 46p of heat transport portions 45 and 46 by caulking, pressure welding, soldering, brazing, bonding, welding, or the like. Protruding portions 45p and 46p are sandwiched between heat sink 51 and fixing plate 87. Fixing plate 87 prevents protruding portions 45p and 46p from coming off from recess 54. Fixing plate 87 is made, for example, of metal or resin. By forming fixing plate 87 from metal, the thermal resistance of the heat transfer path from each of the plurality of circuit components 21, 22, and 23 to cooler 50 is further reduced.

In the sixth modification of the present embodiment, the plurality of protruding portions 45p and 46p of heat transport portions 45 and 46 may be inserted into at least one hole 53 and at least one recess 54.

Each of power conversion apparatuses 1r, 1s, 1t, 1u, 1v, and 1w of the present embodiment achieves the following effects similar to those of power conversion apparatus 1 according to the first embodiment.

Each of power conversion apparatuses 1r, 1s, 1t, 1u, 1v, and 1w of the present embodiment includes the plurality of circuit components 21, 22, and 23, metal base substrate 30 including metal plate 36, a heat transport member (first heat transport member 40), and cooler 50. Metal base substrate 30 includes the first main surface (main surface 33) on which the plurality of circuit components 21, 22, and 23 are mounted, the second main surface (main surface 34) opposite to the first main surface, and the first end surface (end surface 32) connected to the first main surface and the second main surface. Metal plate 36 includes the second main surface. The first end surface faces cooler 50 and is thermally connected to cooler 50. The thermal conductivity of the heat transport member is equal to or higher than the thermal conductivity of metal plate 36. The heat transport member faces the second main surface and is thermally connected to the second main surface. In a plan view of the first main surface, the heat transport member includes protrusion 76 protruding from the first end surface. Cooler 50 is provided with hole 53 or recess 54. Protrusion 76 of the heat transport member is inserted into hole 53 or recess 54 and thermally connected to cooler 50.

Cooler 50 is thermally connected to the first end surface (end surface 32) of metal base substrate 30 and protrusion 76 of the heat transport member. Thus, the heat generated in the plurality of circuit components 21, 22, and 23 is transferred to cooler 50 through both metal base substrate 30 and the heat transport member (first heat transport member 40), and then collected in cooler 50. Even if the number of the plurality of circuit components 21, 22, and 23 increases to thereby increase the size of metal base substrate 30, the plurality of circuit components 21, 22, and 23 can be cooled without increasing the size of cooler 50.

Power conversion apparatuses 1r, 1s, 1t, 1u, 1y, and 1w each include a heat transport member (first heat transport member 40) in addition to metal base substrate 30. Thus, the difference decreases between: the thermal resistance of the heat transfer path extending to cooler 50 from the circuit component (for example, circuit component 21) disposed farther from cooler 50 among the plurality of circuit components 21, 22, and 23; and the thermal resistance of the heat transfer path extending to cooler 50 from the circuit component (for example, circuit component 23) disposed closer to cooler 50 among the plurality of circuit components 21, 22, and 23. Power conversion apparatuses 1r, 1s, 1t, 1u, 1v, and 1w each can more uniformly cool the plurality of circuit components 21, 22, and 23. As a circuit component (for example, circuit component 21) disposed farther from cooler 50 among the plurality of circuit components 21, 22, and 23, a circuit component that generates a larger amount of heat can be adopted. The degree of freedom of arrangement of circuit components 21, 22, and 23 is improved. The thermal design of each of power conversion apparatuses 1r, 1s, 1t, 1u, 1v, and 1w is facilitated.

Protrusion 76 of the heat transport member (first heat transport member 40) is inserted into hole 53 or recess 54, Thus, the vibration resistance of each of power conversion apparatuses 1r, 1s, 1t, 1u, 1v, and 1w is improved.

In each of power conversion apparatuses 1r, 1s, 1t, 1u, 1v, and 1w of the present embodiment, the flow path for refrigerant (cooling pipe 52) is formed in cooler 50.

The heat generated in the plurality of circuit components 21, 22, and 23 is carried by refrigerant to the outside of power conversion apparatus 1. The plurality of circuit components 21, 22, and 23 are efficiently cooled by cooler 50. Cooler 50 can be reduced in size.

In each of power conversion apparatuses 1r, 1s, 1t, 1u, 1v, and 1w of the present embodiment, in the plan view of the first main surface (main surface 33), at least a part of the flow path for refrigerant (cooling pipe 52) overlaps protrusion 76 of the heat transport member (first heat transport member 40).

Thus, the distance between the flow path for refrigerant (cooling pipe 52) and the heat transport member (first heat transport member 40) is reduced. The heat generated in the plurality of circuit components 21, 22, and 23 can be transferred to the flow path for refrigerant with a lower thermal resistance. The plurality of circuit components 21, 22, and 23 are efficiently cooled by cooler 50. Cooler 50 can be reduced in size.

Hereinafter, various aspects of the present disclosure will be summarized as additional aspects.
(Additional Aspect 1)

A power conversion apparatus comprising:
a plurality of circuit components;
a metal base substrate including a metal plate;
a first heat transport member; and
a cooler, wherein
the metal base substrate includes
   a first main surface on which the plurality of circuit components are mounted, and
   a first end surface connected to the first main surface.
a thermal conductivity of the first heat transport member is equal to or higher than a thermal conductivity of the metal plate,
the first heat transport member includes
   a second main surface, and
   a second end surface connected to the second main surface and facing the cooler,
the first end surface and the second end surface are thermally connected to the cooler, and
the second main surface is thermally connected to the metal base substrate.
(Additional Aspect 2)

The power conversion apparatus according to Additional Aspect 1, wherein
the metal base substrate includes a third end surface opposite to the first end surface, and
in a plan view of the first main surface, the first heat transport member extends from the first end surface to the third end surface.
(Additional Aspect 3)

The power conversion apparatus according to Additional Aspect 1, wherein a gap between the metal base substrate and the first heat transport member decreases with an increase in distance from the cooler.
(Additional Aspect 4)

The power conversion apparatus according to Additional Aspect 1, wherein a contact area between the metal base substrate and the first heat transport member increases with an increase in distance from the cooler.
(Additional Aspect 5)

The power conversion apparatus according to Additional Aspect 1, further comprising a metal support member to support the first heat transport member, wherein
the metal base substrate includes a third main surface opposite to the first main surface, the third main surface being connected to the first end surface,
the metal support member includes
   a fourth main surface thermally connected to the third main surface, and
   a fourth end surface connected to the fourth main surface, and
the fourth end surface is thermally connected to the cooler.
(Additional Aspect 6)

The power conversion apparatus according to Additional Aspect 5, wherein, in a plan view of the first main surface, the plurality of circuit components overlap the first heat transport member.
(Additional Aspect 7)

The power conversion apparatus according to Additional Aspect 5, wherein
the first heat transport member includes a plurality of heat transport portions,
each of the plurality of heat transport portions is thermally connected to the metal base substrate and the cooler, and
a distance between at least one of the plurality of heat transport portions and the plurality of circuit components decreases with an increase in distance from the cooler.
(Additional Aspect 8)

The power conversion apparatus according to Additional Aspect 7, wherein, in a plan view of the first main surface, a side surface of the at least one of the plurality of heat transport portions that faces the plurality of circuit components approaches the plurality of circuit components with an increase in distance from the cooler.
(Additional Aspect 9)

The power conversion apparatus according to Additional Aspect 8, wherein
in the plan view of the first main surface, the plurality of circuit components are arranged in a direction away from the cooler, and
in the plan view of the first main surface, the at least one of the plurality of heat transport portions is inclined with respect to the direction in which the plurality of circuit components are arranged.
(Additional Aspect 10)

The power conversion apparatus according to Additional Aspect 8, wherein, in the plan view of the first main surface, a width of the at least one of the plurality of heat transport portions increases with an increase in distance from the cooler.
(Additional Aspect 11)

The power conversion apparatus according to Additional Aspect 10, wherein
in the plan view of the first main surface, the plurality of circuit components are arranged in a direction away from the cooler, and
in the plan view of the first main surface, the side surface of the at least one of the plurality of heat transport portions is inclined with respect to the direction in which the plurality of circuit components are arranged.
(Additional Aspect 12)

The power conversion apparatus according to Additional Aspect 10, wherein, in the plan view of the first main surface, the side surface of the at least one of the plurality of heat transport portions has a stepped shape.
(Additional Aspect 13)

The power conversion apparatus according to Additional Aspect 7, wherein a distance between the metal base substrate and the first heat transport member decreases with an increase in distance from the cooler.
(Additional Aspect 14)

The power conversion apparatus according to Additional Aspect 1, further comprising a metal member thermally connected to the cooler, wherein
the first end surface is thermally connected to the metal member.
(Additional Aspect 15)

The power conversion apparatus according to Additional Aspect 14, wherein an end surface of the metal member that faces the cooler is larger than the first end surface.
(Additional Aspect 16)

The power conversion apparatus according to Additional Aspect 1, wherein
the first heat transport member includes
   a first heat transport portion including the second main surface, and
   a second heat transport portion protruding from the second main surface, and
the second heat transport portion includes the second end surface and is thermally connected to the cooler.
(Additional Aspect 17)

The power conversion apparatus according to Additional Aspect 16, further comprising a metal member thermally connected to the cooler, wherein
the first end surface and the second heat transport portion are thermally connected to the metal member.
(Additional Aspect 18)

The power conversion apparatus according to Additional Aspect 1, further comprising a second heat transport member including a fifth main surface and a fifth end surface connected to the fifth main surface, wherein
the fifth main surface is thermally connected to the plurality of circuit components, and
the fifth end surface is thermally connected to the cooler.
(Additional Aspect 19)

The power conversion apparatus according to Additional Aspect 18, further comprising a metal member thermally connected to the cooler, wherein
the first end surface and the fifth end surface are thermally connected to the metal member.
(Additional Aspect 20)

A power conversion apparatus comprising:
a plurality of circuit components:
a metal base substrate including a metal plate;
a heat transport member; and
a cooler, wherein
the metal base substrate includes
   a first main surface on which the plurality of circuit components are mounted.
   a second main surface opposite to the first main surface, and
   a first end surface connected to the first main surface and the second main surface.
the metal plate includes the second main surface,
the first end surface faces the cooler and is thermally connected to the cooler,
a thermal conductivity of the heat transport member is equal to or higher than a thermal conductivity of the metal plate,
the heat transport member faces the second main surface and is thermally connected to the second main surface,
in a plan view of the first main surface, the heat transport member includes a protrusion protruding from the first end surface.
the cooler is provided with a hole or a recess, and
the protrusion of the heat transport member is inserted into the hole or the recess and thermally connected to the cooler.
(Additional Aspect 21)

The power conversion apparatus according to Additional Aspect 20, wherein the cooler is provided with a flow path for refrigerant.
(Additional Aspect 22)

The power conversion apparatus according to Additional Aspect 21, wherein, in the plan view of the first main surface, at least a part of the flow path overlaps the protrusion of the heat transport member.

It should be understood that the first to thirteenth embodiments and the modifications thereof disclosed herein are illustrative and non-restrictive in every respect. Unless there is inconsistency, at least two of the first to thirteenth embodiments and the modifications thereof disclosed herein may be combined. The scope of the present disclosure is defined by the terms of the claims rather than the description above and is intended to include any modifications within the scope and meaning equivalent to the terms of the claims.

### REFERENCE SIGNS LIST

1, 1b, 1c, 1d, 1e, 1f, 1g, 1h, 1i, 1j, 1k, 1m, 1n, 1p, 1q, 1r, 1s, 1t, 1u, 1v, 1w power conversion apparatus, 2 inverter circuit, 3 transformer circuit, 4 rectifier circuit, S smoothing circuit, 6 input terminal. 7 output terminal, 8 input capacitor, 9a, 9b, 9c, 9d switching element, 10 control circuit, 11 transformer, 11a primary winding, 11b secondary winding, 12a, 12b rectifier element, 13 smoothing reactor, 14 smoothing capacitor, 21, 22, 23, 24, 25, 26 circuit component, 30 metal base substrate, 31, 32 end surface, 33, 34 main surface, 36 metal plate, 37 insulating layer, 38 circuit pattern, 39 conductive bonding member, 40 first heat transport member, 41, 42 end surface, 43, 44 main surface, 45, 46, 47 heat transport portion. 45a, 45b, 45c, 46a, 46b, 46c heat transport element, 45p, 46p protruding portion, 45s, 46s side surface, 48, 49 heat transport portion, 48a, 49a end surface, 50 cooler, 51 heat sink, 52 cooling pipe, 52c central axis, 53 hole, 54 recess, 55 air layer, 60 metal support member, 61, 62 end surface, 63 main surface, 65, 66, 67 groove, 70 metal member, 71, 72 end surface, 73 main surface, 74 hole, 76 protrusion, 80 second heat transport member, 81, 82 end surface, 83 main surface, 85 fixing member, 87 fixing plate.

1-22. (canceled)

23. A power conversion apparatus comprising:
a plurality of circuit components;
a metal base substrate including a metal plate;
a first heat transport member; and
a cooler, wherein
the metal base substrate includes
a first main surface on which the plurality of circuit components are mounted, and
a first end surface connected to the first main surface,
a thermal conductivity of the first heat transport member is equal to or higher than a thermal conductivity of the metal plate,
the first end surface is thermally connected to the cooler, and
the first heat transport member is thermally connected to the cooler and the metal base substrate.

24. The power conversion apparatus according to claim 23, wherein
the first heat transport member includes
a second main surface, and
a second end surface connected to the second main surface and facing the cooler, and
the second end surface is thermally connected to the cooler.

25. The power conversion apparatus according to claim 23, wherein
the metal base substrate includes a third end surface opposite to the first end surface, and
in a plan view of the first main surface, the first heat transport member extends from the first end surface to the third end surface.

26. The power conversion apparatus according to claim 23, wherein a gap between the metal base substrate and the first heat transport member decreases with an increase in distance from the cooler.

27. The power conversion apparatus according to claim 23, wherein a contact area between the metal base substrate and the first heat transport member increases with an increase in distance from the cooler.

28. The power conversion apparatus according to claim 23, further comprising a metal support member to support the first heat transport member, wherein
the metal base substrate includes a third main surface opposite to the first main surface, the third main surface being connected to the first end surface,
the metal support member includes
a fourth main surface thermally connected to the third main surface, and
a fourth end surface connected to the fourth main surface, and
the fourth end surface is thermally connected to the cooler.

29. The power conversion apparatus according to claim 28, wherein, in a plan view of the first main surface, the plurality of circuit components overlap the first heat transport member.

30. The power conversion apparatus according to claim 28, wherein
the first heat transport member includes a plurality of heat transport portions,
each of the plurality of heat transport portions is thermally connected to the metal base substrate and the cooler, and
a distance between at least one of the plurality of heat transport portions and the plurality of circuit components decreases with an increase in distance from the cooler.

31. The power conversion apparatus according to claim 30, wherein, in a plan view of the first main surface, a side surface of the at least one of the plurality of heat transport portions that faces the plurality of circuit components approaches the plurality of circuit components with an increase in distance from the cooler.

32. The power conversion apparatus according to claim 31, wherein
in the plan view of the first main surface, the plurality of circuit components are arranged in a direction away from the cooler, and
in the plan view of the first main surface, the at least one of the plurality of heat transport portions is inclined with respect to the direction in which the plurality of circuit components are arranged.

33. The power conversion apparatus according to claim 23, further comprising a metal member thermally connected to the cooler, wherein
the first end surface is thermally connected to the metal member.

34. The power conversion apparatus according to claim 33, wherein an end surface of the metal member that faces the cooler is larger than the first end surface.

35. The power conversion apparatus according to claim 24, wherein
the first heat transport member includes
a first heat transport portion including the second main surface, and
a second heat transport portion protruding from the second main surface, and
the second heat transport portion includes the second end surface and is thermally connected to the cooler.

36. The power conversion apparatus according to claim 35, further comprising a metal member thermally connected to the cooler, wherein
the first end surface and the second heat transport portion are thermally connected to the metal member.

37. The power conversion apparatus according to claim 23, further comprising a second heat transport member including a fifth main surface and a fifth end surface connected to the fifth main surface, wherein
the fifth main surface is thermally connected to the plurality of circuit components, and
the fifth end surface is thermally connected to the cooler.

38. The power conversion apparatus according to claim 37, further comprising a metal member thermally connected to the cooler, wherein
the first end surface and the fifth end surface are thermally connected to the metal member.

39. A power conversion apparatus comprising:
a plurality of circuit components;
a metal base substrate including a metal plate;
a heat transport member; and
a cooler, wherein
the metal base substrate includes
a first main surface on which the plurality of circuit components are mounted,
a second main surface opposite to the first main surface, and
a first end surface connected to the first main surface and the second main surface,
the first end surface faces the cooler and is thermally connected to the cooler,
a thermal conductivity of the heat transport member is equal to or higher than a thermal conductivity of the metal plate,
the heat transport member faces the second main surface and is thermally connected to the second main surface,
in a plan view of the first main surface, the heat transport member includes a protrusion protruding from the first end surface,
the cooler is provided with a hole or a recess, and
the protrusion of the heat transport member is inserted into the hole or the recess and thermally connected to the cooler.

40. The power conversion apparatus according to claim 39, wherein the cooler is provided with a flow path for refrigerant.

41. The power conversion apparatus according to claim 40, wherein, in the plan view of the first main surface, at least a part of the flow path overlaps the protrusion of the heat transport member.

42. The power conversion apparatus according to claim 39, wherein the metal plate includes the second main surface.
